(19) United States
(12) Patent Application Publication
(10) Pub. No.: US 2024/0186109 A1
(43) Pub. Date: Jun. 6, 2024

(54) METHOD AND APPARATUS FOR REPAIRING A DEFECT OF A SAMPLE USING A FOCUSED PARTICLE BEAM

(71) Applicant: Carl Zeiss SMT GmbH, Oberkochen (DE)

(72) Inventors: Nicole Auth, Gustavsburg (DE); Daniel Rhinow, Frankfurt am Main (DE); Rainer Fettig, Steinmauern (DE)

(21) Appl. No.: 18/442,705

(22) Filed: Feb. 15, 2024

Related U.S. Application Data
(63) Continuation of application No. PCT/EP22/75036, filed on Sep. 8, 2022.

(30) Foreign Application Priority Data
Sep. 10, 2021 (DE) 102021210019.8

(51) Int. Cl. H01J 37/304; H01J 37/153

(52) U.S. Cl. CPC H01J 37/3045; H01J 37/153; H01J 2237/30438

(57) ABSTRACT

The present invention relates to a method for repairing at least one defect of a sample using a focused particle beam, comprising the steps of: (a) producing at least one first local, electrically conductive sacrificial layer on the sample, wherein the first local, electrically conductive sacrificial layer has a first portion and at least one second portion, wherein the first portion is adjacent to the at least one defect and wherein the first portion and the at least one second portion are electrically conductively connected to one another; and (b) producing at least one first reference mark on the at least one second portion of the first local, electrically conductive sacrificial layer for the purposes of correcting a drift of the focused particle beam in relation to the at least one defect while the at least one defect is being repaired.

### CROSS-REFERENCE TO RELATED APPLICATIONS

This application is a continuation of and claims priority under 35 U.S.C. § 120 from PCT Application No. PCT/EP2022/075036, filed on Sep. 8, 2022, which claims priority from German patent application DE 10 2021 210 019.8, entitled “Verfahren und Vorrichtung zum Reparieren eines Defekts einer Probe mit einem fokussierten Teilchenstrahl” [Method and apparatus for repairing a defect of a sample using a focused particle beam], which was filed at the German Patent and Trade Mark Office on Sep. 10, 2021. The entire contents of each of these priority applications are incorporated herein by reference.

### TECHNICAL FIELD

The present invention relates to a method and an apparatus for repairing at least one defect of a sample using a focused particle beam.

### BACKGROUND

As a consequence of the continually increasing integration density in microelectronics, photolithographic masks and/or templates for nanoimprint lithography (NIL) have to image ever smaller structure elements into a photoresist layer of a wafer or into a positive of a substrate or of a wafer. In order to meet these requirements, the exposure wavelength in optical lithography is being shifted to ever shorter wavelengths. At the present time, argon fluoride (ArF) excimer lasers are principally used for exposure purposes, these lasers emitting at a wavelength of 193 nm. To increase the resolution of wafer exposure processes, various variants were developed in addition to conventional binary photolithographic masks. Examples in this respect are phase-shifting masks with different transmissivity levels or alternatingly phase-shifting masks and masks for multiple exposure. There can be a further increase in the resolution by the use of multiple exposures.

Intensive work is being done on lithography systems which use wavelengths in the extreme ultraviolet (EUV) spectral range (10 nm to 15 nm). At present, first memory chips and logic products are being brought to market, the production of which already uses individual masks in EUV technology. The proportion of EUV lithographic layers will increase in future products.

On account of the ever decreasing dimensions of the structure elements, photolithography masks, photomasks or simply masks cannot always be produced without defects that are printable or visible on a wafer. The density of visible or printable defects of a photomask increases drastically as structure dimensions become smaller. At present, EUV masks have the greatest number of defects on account of the utilized exposure wavelength. The problem of defective stamps or templates likewise is more acute in nanoimprint lithography. This is mainly due to the circumstances that in NIL—unlike in optical lithography—defective stamps or templates transfer their defects 1:1 onto the positive to be structured, which is arranged on a wafer or, in general terms, on a substrate.

On account of the great expense involved in the production of photomasks and/or templates for NIL, defective masks and/or stamps are always repaired where possible. Two important groups of defects of masks or stamps are, firstly, dark defects. These are sites at which material is present, but which should be free of this material. These defects are repaired by removing the excess material preferably with the aid of a local etching process.

Secondly, there are so-called clear defects. These are local defects on the photomask which, upon optical exposure in a wafer stepper or wafer scanner, have a greater light transmissivity than an identical defect-free reference position. Within the scope of repair processes, these defects can be rectified by a local deposition of a material having suitable optical properties on the mask or the stamp.

Typically, the mask or stamp defects are corrected by particle beam-induced local etching processes and/or local deposition processes. A shift in position between the element to be corrected and a particle beam used for the repair may occur during the local processing processes on account of various influences, for example thermal and/or mechanical drifts. Further, the micromanipulators used to align the defect on the particle beam used for repair purposes have an electrical or mechanical drift over time.

In order to minimize these effects, reference structures or reference marks are applied in the vicinity of the processing site on a sample and are scanned at regular intervals. The measured deviations of the positions of the reference marks with respect to a reference position are used during a processing procedure of the sample for the purposes of correcting the beam position of the particle beam. This is referred to as “drift correction.” The reference marks used to this end are referred to as “DC marks” in the art.

The documents listed below consider the topic of reference marks: U.S. Pat. No. 7,018,683, EP 1 662 538 A2, JP 2003-007247 A, US 2007/0023689, US 2008/0073580, U.S. Pat. No. 6,740,456 B2, US 2010/0092876 A1 and U.S. Pat. No. 5,504,339.

Reference structures or reference marks are frequently produced by virtue of depositing material in the vicinity of the site of the sample to be processed. Where possible, the reference marks are applied to sites on a photomask where said reference marks do not interfere with the operation of a mask. By way of example, these are elements of the absorber pattern in the case of binary photomasks. As a result of the decreasing size of the pattern elements, the reference marks have dimensions which reach or sometimes exceed the size of elements of the absorber pattern. Then again, the reference marks always have to be removed after a processing process in certain mask types; by way of example, this applies to phase-shifting masks. Likewise, reference marks have to be removed from a repaired stamp that is intended to be used in NIL.

The U.S. Pat. No. 9,721,754 B2 of the applicant describes reference marks, the production of which uses material which can be removed from the mask by use of a standard mask cleaning process. However, the materials suitable for this process usually have a low resistance vis-à-vis the local etching processes of a processing process. On account of this flaw, the deposited reference marks change so significantly during a processing process of the mask that there is a drastic reduction in the accuracy with which the position of the respective reference mark can be determined.

The laid-open application DE 10 2018 217 025 A1 describes the application of reference marks to sacrificial layers in order to protect a sample when scanning the reference mark by way of a particle beam.

In the article “Metal assisted focused-ion beam nanopatterning,” Nanotechnology, 27 (2016) 36LT01, the authors A. Kannegulla and L.-J. Cheng describe the use of a metallic sacrificial layer for the purposes of preventing edges of an NIL stamp from rounding off as a result of the sputtering effect of a focused ion beam.

Further problems may occur in addition to the above-described change in the reference marks, which limit their function within the scope of drift correction or even render this impossible. A problem that may occur within the scope of processing processes carried out in the form of local deposition processes is that material used to correct clear defects is inadvertently deposited on the sample around the defect during a deposition procedure. This material deposited around the defect can only be removed from a sample with great difficulty since the material used for the defect correction should adhere permanently to the repaired site. The correction material inadvertently deposited around the defect to be repaired causes a deterioration in the operational behavior of the repaired mask or of the repaired stamp.

Moreover, particle beam-induced repair processes may lead to the generation and/or introduction of charges in masks or, more generally, in samples. Electrostatic charging of the sample, in particular an inhomogeneous distribution of the electrostatic potential accompanying this, leads to distortions when imaging a site to be processed and/or when scanning a reference mark using a charged particle beam, and as a result leads to a deterioration in the quality of the repair processes.

The present invention is therefore based on the problem of specifying a method and an apparatus which can at least partly avoid the above-described difficulties when repairing a sample using a focused particle beam.

### SUMMARY

In accordance with a first exemplary embodiment of the present invention, this problem is solved by means of a method according to claim 1 and an apparatus according to claim 26. In accordance with a second exemplary embodiment of the present invention, this problem is solved by means of a method according to claim 2 and an apparatus according to apparatus claim 27.

In an embodiment, a method for repairing at least one defect of a sample using a focused particle beam comprises: producing at least one first sacrificial layer on the sample adjacent to the at least one defect for correcting a drift of the focused particle beam in relation to the at least one defect during the repairing of the at least one defect.

During a repairing process of a sample using a particle beam induced etching process or using a particle beam induced deposition process, the particle beam may drift with respect to a defect to be corrected. For example, the drift may be caused by a thermal drift of the sample stage. A sacrificial layer may be used for correcting a drift of the focused particle beam. The sacrificial layer adjacent to the defect may be in the immediate vicinity of the defect and thus accessible quickly for drift assessment and/or correction. Specifically, a structure related to the sacrificial layer may be used for drift correction. For example, a reference mark may be deposited on the sacrificial layer which may be used for detecting a drift of the focused particle beam relative to the defect to be repaired, but this is not mandatory. The sacrificial layer may be produced such that it is suitable for depositing a reference mark thereon.

In a further embodiment, a method for repairing at least one defect of a sample using a focused particle beam comprises: producing at least one first electrically conductive sacrificial layer on the sample for correcting a drift of the focused particle beam in relation to the at least one defect during the repairing of the at least one defect.

Samples to be repaired frequently are electrical insulators or at best have semiconducting properties. Examples of the first group are the quartz substrates of photomasks or NIL stamps. Examples of the latter group are integrated circuits (ICs) to be produced on a wafer. A particle beam can generate electrical charges in the sample and/or a sacrificial layer when scanning the sample and/or the sacrificial layer. This process may equally occur when scanning a defect to be repaired. As a result, different local electrostatic charges of a sample may be generated during a defect repair. But a sacrificial layer which is electrically conductive balances local electrostatic charges so that the focused particle beam “sees” an equal electrostatic potential when scanning the sacrificial layer. Thus, an electrically conductive sacrificial layer increases the precision of the position determination of a focused particle beam during the repair process of a defect of the sample. Therefore, an electrically conductive sacrificial layer improves a drift correction of the focused particle beam during a defect repair process.

The first sacrificial layer may comprise a first electrically conductive sacrificial layer and/or a first local sacrificial layer (e.g. a first local, electrically conductive sacrificial layer). The first electrically conductive sacrificial layer may comprise a first local, electrically conductive sacrificial layer.

A focused particle beam generates electric charges (exclusively) in a first local, electrically conductive sacrificial layer. On account of the electrical conductivity of the first sacrificial layer, generated electric charges can be distributed uniformly over the first sacrificial layer. Consequently, a charged particle beam sees substantially the same electrostatic potential when scanning a reference mark that may be placed on or close to the sacrificial layer and a defect. Different deflections of the charged particle beam when scanning over the defect and the electrically conductive sacrificial layer, and hence different distortions of the image representation of for example a reference mark arranged on the electrically conductive sacrificial layer and the defect, are prevented. Thus, the quality of the drift correction can be increased, and hence the quality of the defect correction process can be improved.

The expression “substantially” here, as at other places in this description, denotes an indication of a measured variable within the customary error limits when using metrology according to the prior art.

In this application, the expression “local sacrificial layer” means that the sacrificial layer does not extend over the entire sample. Rather, the first sacrificial layer can be deposited around a defect or wholly or partly on a defect and around the latter with the aid of a local particle beam-induced deposition process. By way of example, the lateral extents of the local sacrificial layer can be less than 1 mm, less than 500 μm or less than 100 μm.

The focused particle beam may comprise a focused electron beam.

More generally, the focused particle beam may comprise at least one element from the following group: a photon beam, an electron beam, an ion beam, an atomic beam and a molecular beam. The photon beam may include a photon beam from the ultraviolet (UV), the deep ultraviolet (DUV) or the extreme ultraviolet (EUV) wavelength range.

Preferably the focused particle beam comprises a focused electron beam and/or a focused ion beam. Electron beams and ion beams can be focused on a much smaller spot than photon beams, and thus facilitate a greater spatial resolution during a defect repair. Moreover, electron beams and ion beams can be produced and imaged more easily than atomic beams or molecular beams.

Scanning a sample with a focused particle beam may cause damage in the scanned region of the sample. The extent of the damage occurring depends on the type of particle beam. For instance, an ion beam, an atomic beam or a molecular beam causes great damage in the scanned region as a result of the large momentum transfer from the massive particles to the lattice of the sample. Moreover, some of the particles of an ion, atomic or molecular beam are incorporated into the lattice of the sample, as a result of which its properties, for instance its optical properties, are locally modified.

By contrast, an electron beam—on account of the low electron mass—only typically makes very little damage in the scanned region of the sample. As a result, the use of electrons when repairing defects facilitates defect processing of a sample largely without side effects. Therefore, as a rule, the use of electrons should be preferred over the use of ions in a focused particle beam.

The above defined methods may further comprise the step of producing at least one first reference mark on the first sacrificial layer.

Producing the at least one first reference mark may comprise: producing the at least one first reference mark at a distance from the at least one defect such that the repair of the at least one defect substantially does not change the at least one first reference mark.

First reference marks which are used to correct a drift during a defect repair process and which are applied in the direct vicinity of a defect to be repaired may be modified by repair processes, and thus may be impaired in their function as a means for drift correction. Firstly, material may be deposited forming a first reference mark during a local deposition process and, secondly, a repair process in the form of an etching process may alter the structure of the first reference mark. The method described in this application allows the application of a first reference mark at a distance from the defect to be repaired, at which distance the repair process substantially does not change the at least one first reference mark.

The at least one first reference mark may comprise a lateral extent of 1 nm to 1000 nm, preferably of 2 nm to 500 nm, more preferably of 5 nm to 100 nm and most preferably of 10 nm to 50 nm. Moreover, a further demand in respect of the maximum extent of a reference mark emerges from the condition that the lateral extent of a reference mark must not be greater than the field of view of a scanning particle microscope.

The first sacrificial layer may have a first portion and at least one second portion, wherein the first portion may be adjacent to the at least one defect, wherein the first portion and the at least one second portion may be electrically conductively connected to one another.

Both the first portion and the at least one second portion are electrically conductive in a first electrically conductive sacrificial layer. The electrical conductivities of the first portion, of the at least one second portion and of the connection(s) between the first and the at least one second portion can be the same or vary slightly. In this application, the term “electrically conductive” denotes a sacrificial layer with a specific electrical resistance of the order of metallic conductors, that is to say ρ<1 Ω·cm.

The first portion may have a lateral extent around the at least one defect such that repairing the at least one defect substantially does not damage the sample.

The first portion of the first sacrificial layer represents a protective layer during a defect processing process or a defect repair process. The latter can be adapted, firstly, to the dimensions of the defect to be repaired and to the focal diameter of the particle beam used for the repair and, secondly, to the type of defect repair to be carried out. In the context above, the expression “substantially” means that no impairment of the functionality of the sample as a consequence of the implemented repair process can be substantiated following the defect repair.

A defect repair is preferably carried out within a field of view of the focused particle beam. This embodiment is advantageous in that the parameters of an apparatus that provides the particle beam do not need to be modified for the purposes of scanning the first reference mark during the repair process. This allows the best possible correction of a drift. By way of example, a field of view of a scanning particle microscope may comprise an area of 1000 μm×1000 μm, preferably 100 μm×100 μm, more preferably 10 μm×10 μm, and most preferably 6 μm×6 μm.

It is also possible that the lateral dimensions of the first sacrificial layer exceed the field of view of the focused particle beam. By way of example, this may occur in the case of large defects that are to be repaired. The first portion may have a lateral extent around the edge of the at least one defect which extends over a range of 1 nm to 1000 μm, preferably 2 nm to 200 μm, more preferably 5 nm to 40 μm, and most preferably 10 nm to 10 μm.

A thickness of the first portion may comprise a range of 0.1 nm to 1000 nm, preferably of 0.5 nm to 200 nm, more preferably of 0.5 nm to 200 nm and most preferably of 2 nm to 50 nm.

Producing the at least one reference mark may comprise: producing the at least one first reference mark at a distance from the at least one defect such that the repair of the at least one defect substantially does not influence the correction of the drift.

This feature ensures that the structure of a first reference mark remains substantially unchanged during a processing process. Therefore, the function of the first reference mark is maintained without restrictions throughout the entire repair process.

The above defined methods may further comprise the step of producing at least one first reference mark on the at least one second portion of the first sacrificial layer for correcting a drift of the at least one defect during repairing of the at least one defect.

The above defined methods may further comprise determining at least one first reference distance between the at least one first reference mark and the at least one defect before repairing the at least one defect.

The adjacency of the first portion to the at least one defect may comprise at least one element from the following group: adjacency of the first portion to an edge of the at least one defect, partial coverage of the at least one defect by the first portion and complete coverage of the at least one defect by the first portion.

By virtue of the sacrificial layer edging the defect at the start of the repair process, a charged particle beam substantially “sees” the same electrostatic potential when scanning the at least one first reference mark and the defect to be repaired. Moreover, the first sacrificial layer edging the defect can effectively protect the sample from the influence of the repair process. By way of example, deposition material may inadvertently be deposited on the first sacrificial layer around the defect. Moreover, a first sacrificial layer which edges a defect of excess material to be repaired protects the region of the sample around the defect while a local etching process is carried out for the purposes of repairing the sample.

Once the repair process has been terminated, the first sacrificial layer can be removed from the sample together with the deposition material situated on said first sacrificial layer. As a result, carrying out a method according to the invention facilitates a correction of defects substantially without residue and consequently simultaneously facilitates a further increase in the quality of defect repair processes in addition to an improved drift correction.

The adjacency of the first portion to the edge of the at least one defect may comprise: adjacency of the first portion to an entire edge of the at least one defect. This embodiment is advantageous in particular for defects located in isolation on a sample.

The at least one second portion may extend over at least one scanning region of the focused particle beam for detecting the at least one first reference mark.

The first sacrificial layer may have a lateral extent determined by the lateral extent of the first portion and the number of at least one second portions.

The first portion and the at least one second portion may be interconnected in flush fashion. A flush connection between the first and the one or more second portions requires the greatest outlay for depositing a corresponding first sacrificial layer. Then again, a large-area first sacrificial layer has a high capacitance such that electrostatic charging caused by scanning the at least one reference mark and/or caused by a focused particle beam during the defect repair changes the electrostatic potential of the first sacrificial layer to only a small extent.

The electrically conductive connection between the first and the at least one second portion may comprise a width in the range of 0.1 nm to 1000 μm, preferably of 20 nm to 100 μm, more preferably of 30 nm to 10 μm and most preferably of 40 nm to 3 μm.

A thickness of an electrically conductive connection between the first and the at least one second portion may comprise a range of 0.1 nm to 1000 nm, preferably of 0.5 nm to 200 nm, more preferably of 1 nm to 100 nm and most preferably of 2 nm to 50 nm.

The connection of the first portion and the at least one second portion in the form of an electrically conductive connection may be advantageous when the first and the at least one second portion are at different levels. By way of example, the first portion may be arranged on the substrate of a photomask and the at least one second portion may be located on a pattern element of the photomask.

The at least one second portion may extend over at least one scanning region of the focused particle beam for the purposes of detecting the at least one first reference mark.

At least a majority of the particles of a focused particle beam may be incident on the at least one second portion of the first sacrificial layer while determining the position of the at least one first reference mark. A lateral extent of the at least one second portion may exceed the scanning region of the focused particle beam for scanning the at least one first reference mark by a factor of 1.2, preferably a factor of 1.5, more preferably a factor of 2 and most preferably a factor of 3.

What is ensured by virtue of the at least one second portion around the at least one first reference mark being greater by a defined factor than the scanning region scanned by the focused particle beam for the purposes of determining the position of the at least one first reference mark is that the scanning of the at least one first reference mark is performed substantially completely on the first sacrificial layer, even in the case of a significant drift of the focused particle beam relative to the defect. This precludes an uncontrollable local generation of electrical charge carriers in the sample.

An additional degree of freedom is obtained by attaching the at least one first reference mark to a first sacrificial layer—rather than a direct deposition on the sample. Thus, the first sacrificial layer can be designed such that the latter can easily and substantially completely be removed from a sample at the end of a processing process of the sample. Untouched by this constraint, the at least one first reference mark can be designed such that the latter withstands both multiple determination of the position of the first reference mark and one or more extensive processing processes of the sample substantially unchanged.

By way of example, the area of the at least one second portion of the deposited first sacrificial layer can be square or rectangular. The lateral dimension relates to the shorter of the sides of a rectangle. The area of the at least one second portion can be adapted to the area of the scanning region of the at least one focused particle beam.

A lateral extent of the at least one second portion may have lateral dimensions in a range of 10 nm to 1000 μm, preferably 50 nm to 500 μm, more preferably 200 nm to 100 μm, and most preferably 500 nm to 50 μm.

A thickness of the at least one second portion may comprise a range of 0.1 nm to 1000 nm, preferably of 0.5 nm to 200 nm, more preferably of 1 nm to 100 nm and most preferably of 2 nm to 50 nm.

Producing the at least one first sacrificial layer may comprise: depositing the first sacrificial layer by the focused particle beam in combination with a first precursor gas. The focused particle beam may comprise an electron beam.

The at least one first precursor gas may comprise: at least one first deposition gas for depositing the first portion of the first sacrificial layer, at least one second deposition gas for depositing the at least one second portion of the first sacrificial layer, and at least one third deposition gas for depositing the electrically conductive connection of the first sacrificial layer. The at least one first, the at least one second and the at least one third deposition gas may comprise a single deposition gas, two different deposition gases or three different deposition gases. The various functions of the first portion and of the one or more second portions and of the electrically conductive connection can be optimized by respectively adapted material compositions.

The at least one first precursor gas may comprise molybdenum hexacarbonyl (Mo(CO)₆) and nitrogen dioxide (NO₂) as an additive gas, and/or the first precursor gas may comprise chromium hexacarbonyl (Cr(CO)₆).

Producing the at least one first reference mark may comprise: depositing the at least one first reference mark using a focused particle beam in combination with at least one second precursor gas. The focused particle beam for depositing the at least one first reference mark may comprise an electron beam.

The first sacrificial layer and the at least one first reference mark may be deposited using one particle beam or using different particle beams. By way of example, the first sacrificial layer may be deposited using an electron beam and the at least one second reference mark may be deposited using an ion beam.

The at least one first precursor gas for depositing the first sacrificial layer may comprise at least one element from the following group: metal alkyls, transition element alkyls, main group alkyls, metal carbonyls, transition element carbonyls, main group carbonyls, metal alkoxides, transition element alkoxides, main group alkoxides, metal complexes, transition element complexes, main group complexes and organic compounds.

The at least one second precursor gas for depositing the at least one reference mark may comprise at least one element from the following group: metal alkyls, transition element alkyls, main group alkyls, metal carbonyls, transition element carbonyls, main group carbonyls, metal alkoxides, transition element alkoxides, main group alkoxides, metal complexes, transition element complexes, main group complexes and organic compounds.

The metal alkyls, transition element alkyls and main group alkyls may comprise at least one element from the following group: cyclopentadienyl (Cp) trimethyl platinum (CpPtMe₃), methylcyclopentadienyl (MeCp) trimethyl platinum (MeCpPtMe₃), tetramethyltin (SnMe₄), trimethylgallium (GaMe₂), ferrocene (Co₂Fe) and bisarylchromium (Ar₂Cr). The metal carbonyls, transition element carbonyls and main group carbonyls may comprise at least one element from the following group: chromium hexacarbonyl (Cr(CO)₆), molybdenum hexacarbonyl (Mo(CO)₆), tungsten hexacarbonyl (W(CO)₆), dicobalt octacarbonyl (Co₂(CO)₈), triruthenium dodecacarbonyl (Ru₃(CO)₁₂) and iron pentacarbonyl (Fe(CO)₅). The metal alkoxides, transition element alkoxides and main group alkoxides may comprise at least one element from the following group: tetraethyl orthosilicate (TEOS, Si(OC₂H₅)₄) and tetraisopropoxytitanium (Ti(OC₃H₇)₄). The metal halides, transition element halides and main group halides may comprise at least one element from the following group: tungsten hexafluoride (WF₆), tungsten hexachloride (WCl₆), titanium hexachloride (TiCl₆), boron trichloride (BCl₃) and silicon tetrachloride (SiCl₄). The metal complexes, transition element complexes and main group complexes may comprise at least one element from the following group: copper bis(hexafluoroacetylacetonate) (Cu(C₅F₆HO₂)₂) and dimethylgold trifluoroacetylacetonate (Me₂Au(C₅F₃H₄O₂)). The organic compounds may comprise at least one element from the following group: carbon monoxide (CO), carbon dioxide (CO₂), aliphatic hydrocarbons, aromatic hydrocarbons, constituents of vacuum pump oils and volatile organic compounds.

Producing the at least one first reference mark may comprise: etching at least one depression into the at least one second portion of the first sacrificial layer. Etching the at least one depression may comprise: carrying out a local etching process using a focused particle beam in combination with at least one third precursor gas. The focused particle beam may comprise an electron beam and/or an ion beam.

The at least one third precursor gas may comprise at least one etching gas. The at least one etching gas may comprise one element from the following group: a halogen-containing compound and an oxygen-containing compound. The halogen-containing compound may comprise at least one element from the following group: fluorine (F₂), chlorine (Cl₂), bromine (Br₂), iodine (I₂), xenon difluoride (XeF₂), dixenon tetrafluoride (Xe₂F₄), hydrofluoric acid (HF), hydrogen iodide (HI), hydrogen bromide (HBr), nitrosyl chloride (NOCl), phosphorus trichloride (PCl₃), phosphorus pentachloride (PCl₅) and phosphorus trifluoride (PF₃). The oxygen-containing compound may comprise at least one element from the following group: oxygen (O₂), ozone (O₃), water vapour (H₂O), hydrogen peroxide (H₂O₂), nitrous oxide (N₂O), nitrogen oxide (NO), nitrogen dioxide (NO₂) and nitric acid (HNO₃).

The at least one first, the at least one second and/or the at least one third precursor gas may comprise at least one additive gas from the following group: an oxidizing agent, a halide and a reducing agent.

The oxidizing agent may comprise at least one element from the following group: oxygen (O₂), ozone (O₃), water vapour (H₂O), hydrogen peroxide (H₂O₂), nitrous oxide (N₂O), nitrogen oxide (NO), nitrogen dioxide (NO₂) and nitric acid (HNO₃). The halide may comprise at least one element from the following group: chlorine (Cl₂), hydrochloric acid (HCl), xenon difluoride (XeF₂), hydrofluoric acid (HF), iodine (I₂), hydrogen iodide (HI), bromine (Br₂), hydrogen bromide (HBr), nitrosyl chloride (NOCl), phosphorus trichloride (PCl₃), phosphorus pentachloride (PCl₅) and phosphorus trifluoride (PF₃). The reducing agent may comprise at least one element from the following group: hydrogen (H₂), ammonia (NH₃) and methane (CH₄).

The first precursor gas may comprise molybdenum hexacarbonyl (Mo(CO)₆) and the at least one additive gas may comprise nitrogen dioxide (NO₂), and/or the second precursor gas may comprise tetraethyl orthosilicate (Si(OC₂H₅)₄) or chromium hexacarbonyl (Cr(CO)₆).

Removing the first portion of the first sacrificial layer which covers the at least one defect may comprise: carrying out a particle beam-induced etching process using at least one fourth precursor gas. The at least one fourth precursor gas may comprise at least one second etching gas. The at least one second etching gas may comprise at least one element from the group of the first etching gases listed above. The first deposition gas for depositing the first portion of the sacrificial layer may comprise an element from the group of: chromium hexacarbonyl (Cr(CO)₆) and molybdenum hexacarbonyl (Mo(CO)₆), and the at least one second etching gas for removing the first portion of the sacrificial layer may comprise nitrosyl chloride (NOCl), on its own or in combination with at least one additive gas, for instance water (H₂O).

The precursor gas for etching at least one first reference mark into the at least one second portion of the first sacrificial layer may comprise xenon difluoride (XeF₂) in combination with an additive gas, for example oxygen (O₂), water (H₂O) or chlorine (Cl₂). Alternatively, e.g. nitrosyl chloride (NOCl), on its own or in combination with an additive gas, for instance water (H₂O), may be used for generating a first reference mark.

The above defined methods may further comprise removing a part of the first portion of the first sacrificial layer which covers the at least one defect before repairing the at least one defect.

The at least one defect may comprise a defect of excess material and the method may further comprise: repairing the at least one defect at least partly through the first sacrificial layer.

A first sacrificial layer or a first portion of a first sacrificial layer which partly or fully extends over a defect of excess material to be repaired may be removed in a single process step from the sample, for example using a local particle beam-induced etching process. In this case, the etching gas and/or an additive gas can be adapted to the progress of the etching process—if the etching rates of the defect and of the material of the first portion of the first sacrificial layer differ significantly from one another. Moreover, it is possible to adapt further beam parameters of the particle beam and/or further process parameters to the progress of the etching process. The progress of the local etching process can be determined by analyzing the backscattered or secondary electrons generated during the etching process. Moreover, or alternatively, the material of the removed material can be analyzed, for instance by way of a SIMS (secondary ion mass spectroscopy) analysis. To this end, an ion beam is preferably used as a particle beam. Further, the etching rates can be calibrated by virtue of the etching processes of the sacrificial layer and for the material to be removed being optimized separately from one another. By way of example, this can be implemented by carrying out etching sequences.

The first and the at least one second portion of the first sacrificial layer may have lateral extents such that the action of repairing the at least one defect distorts an image section comprising the at least one defect by no more than 10%, preferably by no more than 5%, more preferably by no more than 2% and most preferably by no more than 1%. The action of repairing a defect with the aid of a focused particle beam may lead to electrostatic charging of the electrically conductive sacrificial layer. The electrostatic charging of the sacrificial layer may lead to a distortion of the image section containing the defect or a defect residue. The distortion of the image section is related to the image section before the repair process has started.

Electrostatic charging of the sacrificial layer may locally influence imaging parameters of the focused particle beam and said imaging parameters may consequently be subject to local variations. A local change, for instance a local variation of the magnification of an image produced with the aid of a scanning focused particle beam, results in a distortion of the image in comparison with an image whose magnification has no local variation of the imaging parameters, for example the magnification.

The first portion, the at least one second portion and the electrically conductive connection may have a material composition which comprises at least one element from the following group: a metal, a metal-containing compound, a conductive ceramic and a doped semiconductor compound.

The metal may comprise at least one element from the following group: molybdenum, cobalt, chromium, niobium, tungsten, rhenium, ruthenium and titanium. The metal-containing compound may comprise at least one element from the following group: a molybdenum alloy, a cobalt-containing compound, a chromium-containing compound, a niobium-containing compound, a tungsten-containing compound, a rhenium-containing compound and a titanium-containing compound. The metal-containing compound may comprise elements from the following group: nitrogen, oxygen, fluorine, chlorine, carbon and silicon. The doped semiconductor compound may comprise at least one element from the following group: indium tin oxide (ITO), aluminum-doped zinc oxide (AZO), antimony-doped tin oxide (ATO), and fluorine-doped tin oxide (FTO). The conductive ceramic may comprise molybdenum silicide.

The first portion, the at least one second portion and the electrically conductive connection may have different material compositions.

The first sacrificial layer and the at least one first reference mark may have different material compositions.

In addition to the topology contrast of the first reference mark, this also yields a material contrast between the at least one second portion of the first sacrificial layer and the at least one first reference mark when the at least one first reference mark is scanned.

The at least one defect may comprise a defect of excess material and the action of repairing the at least one defect may comprise: choosing a material composition of the first portion of the first sacrificial layer, of the at least one second etching gas, and/or of the at least one additive gas such that an etching rate of an etching process induced by a focused particle beam is substantially the same for the at least one defect and the first portion.

The rounding of curves at the edge of the etching region, which occurs in the case of local etching of a defect, can be minimized by satisfying this condition. Further, under-etching of the sample within the scope of a defect correction can be avoided. At the same time, observing this condition facilitates the production of maximally steep side walls of an etched region of the sample.

A sample may comprise a lithographic sample. The lithographic sample may comprise at least one element from the following group: a photomask and a stamp for nanoimprint lithography (NIL). However, a sample may also comprise at least one element from the following group: a photomask, a stamp for NIL, an integrated circuit (IC), a photonic integrated circuit (PIC), a microsystem (a MEMS, micro-electromechanical system, or a MOEMS, a micro-optoelectromechanical system) and a printed circuit board (PCB). The integrated circuit and/or the photonic integrated circuit may be arranged on a wafer. A photomask may be any type of transmissive or reflective photomask, for example a binary or a phase-shifting mask.

The method may further comprise: determining at least one first reference distance between the at least one first reference mark and the at least one defect before starting the repair of the at least one defect.

In combination with the at least one first reference mark, the at least one first reference distance can be used to correct a drift of the at least one defect relative to the focused particle beam during a defect repair process.

The at least one first reference mark may comprise a height in the range of 1 nm to 1000 nm, preferably of 2 nm to 500 nm, more preferably of 5 nm to 200 nm and most preferably of 10 nm to 100 nm.

The method may further comprise: scanning the sample with the focused particle beam for the purposes of producing a defect map of the sample.

Scanning the sample may comprise scanning the at least one defect of the sample using a focused particle beam. The focused particle beam for scanning the sample may comprise the particle beam used to produce the first sacrificial layer, to generate the at least one first reference mark and/or to initiate a local defect processing process. However, it is also possible within the scope of scanning the sample to use a first particle beam, for instance a photon beam, to identify the at least one defect and to use a second particle beam, for example an electron beam, to detect a contour of a repair shape of the at least one defect.

The apparatus which carries out the above-described method may receive the coordinates of the at least one defect of the sample from a sample inspection apparatus. The defect map of the sample may include the at least one defect of the sample. In particular, the defect map may include a repair shape for repairing the at least one defect.

The method may further comprise: producing at least one second reference mark on the sample and determining at least one second reference distance between the at least one second reference mark and the at least one defect before producing the first sacrificial layer.

Further, the method may comprise: producing at least one second sacrificial layer on the sample, depositing at least one second reference mark on the at least one second sacrificial layer and determining at least one second reference distance between the at least one second reference mark and the at least one defect before the production of the first sacrificial layer has started.

The at least one second reference mark is required to correct a drift during the deposition of the first sacrificial layer. Further, the at least one second reference mark is required for correcting a drift during the removal of the first portion of the first sacrificial layer which covers the at least one defect. Therefore, for reasons of process economy, it may be advantageous to dispense with the deposition of the at least one second sacrificial layer and apply the second reference mark(s) directly to the sample. Then again, the deposition of the at least one second sacrificial layer provides an additional degree of freedom which can be used to simplify the removal of the at least one second reference mark from the sample.

The at least one second reference distance may be greater than the at least one first reference distance.

The at least one second reference distance and the at least one second reference mark are required to correct a drift between the focused particle beam and the at least one defect while the first sacrificial layer is deposited. It is therefore very advantageous if the at least one second reference mark is not covered by the first sacrificial layer. This ensures the function of the at least one second reference mark.

Moreover, the method may comprise: correcting a drift while performing at least one element from the following group: producing the first sacrificial layer and removing a first portion of the first sacrificial layer which covers the at least one defect from the at least one defect by using the at least one second reference mark and the at least one second reference distance.

The duration of the process processing can be optimized by virtue of the first sacrificial layer being deposited as precisely as possible in relation to the defect to be repaired. By way of example, should it be possible to deposit the first sacrificial layer around the defect without substantially covering the latter, it is possible to dispense with the etching process for removing the first portion of the first sacrificial layer for the purposes of exposing the defect prior to the repair thereof.

The method may further comprise: jointly removing the first sacrificial layer and the at least one first reference mark from the sample within the scope of a wet chemical and/or mechanical cleaning process.

It is an advantage of the method described here that the at least one first reference mark can be removed, together with the first sacrificial layer, from the sample in a standard cleaning process. The methods further allow matching of the material composition of the first sacrificial layer to the sample such that the first sacrificial layer can fully fulfil its various functions during a defect processing process and, moreover, can easily be removed from the sample once the defect repair has been terminated.

Moreover, the method may comprise: jointly removing the first sacrificial layer, the at least one first reference mark and the at least one second reference mark from the sample within the scope of a wet chemical cleaning process.

The method may additionally comprise: jointly removing the first sacrificial layer, the at least one second sacrificial layer, the at least one first reference mark and the at least one second reference mark from the sample within the scope of a wet chemical and/or mechanical cleaning process.

The wet chemical cleaning process can be carried out using water and at least one oxidizing gas dissolved therein. The oxidizing gas may comprise at least one element from the following group: oxygen (O₂), nitrogen (N₂) and hydrogen (H₂). Furthermore, it is possible for an aqueous cleaning solution to have a pH value <5, preferably <3.5, more preferably <2 and most preferably <1.

The mechanical cleaning process may comprise the application of ultrasound and/or megasound. Cleaning by exerting the action of a physical force on the region of the samples to be cleaned is also possible.

Further, the method may comprise: jointly removing the first sacrificial layer and the at least one first reference mark from the sample by use of a focused particle beam-induced etching process. Moreover, it is conceivable to use a particle beam, for example a photon beam, to remove the first sacrificial layer and the at least one first reference mark.

The method may additionally comprise: jointly removing the first sacrificial layer, the at least one first reference mark and the at least one second reference mark from the sample by use of an etching process induced by a focused particle beam.

The method may moreover comprise: jointly removing the first sacrificial layer, the at least one second sacrificial layer, the at least one first reference mark and the at least one second reference mark from the sample with the aid of an etching process induced by a focused particle beam.

With the aid of a local etching process which is induced by a focused particle beam, it is also possible to remove the at least one first reference mark, the at least one second reference mark from the sample together with the first sacrificial layer and/or the at least one second sacrificial layer. The focused particle beam for removing the first and/or the second reference mark(s) and the first and/or the second sacrificial layer(s) can be the particle beam that is used to produce the reference mark(s) and/or the sacrificial layer(s). Moreover, the focused particle beam can be the particle beam used to carry out the defect processing. The material composition of the sacrificial layer(s) can be chosen from the viewpoint of simple removability, for instance a simple etchability of the sacrificial layer(s) by a local particle beam-induced etching process. The preferred particle beam for joint removal of the sacrificial layer(s) and the reference mark(s) comprises an electron beam.

It is an advantage of the method described in this application that both the sacrificial layer(s) and the reference mark(s) can be generated using a single apparatus and the apparatus can simultaneously be used to process the at least one defect and remove the sacrificial layer(s) together with the associated reference mark(s). This means there is no need during the entire defect repair process to break the vacuum prevalent in the apparatus.

A sample may have at least one defect, which is repaired using the method described above.

A computer program can comprise instructions that prompt a computer system to carry out the method steps explained above. The computer program can be stored in a computer-readable storage medium.

In an embodiment, an apparatus (200) for repairing at least one defect of a sample using a focused particle beam, comprises: means for producing at least one first sacrificial layer on the sample adjacent to the at least one defect for correcting a drift of the focused particle beam in relation to the at least one defect during the repairing of the at least one defect.

In another embodiment, an apparatus for repairing at least one defect of a sample using a focused particle beam comprises: means for producing at least one first electrically conductive sacrificial layer on the sample for correcting a drift of the focused particle beam in relation to the at least one defect during the repairing of the at least one defect.

The means for producing the first sacrificial layer comprises means for producing a first local electrically conductive sacrificial layer.

The apparatus may further comprise an electron column having a single-stage condenser system.

The means for producing the first sacrificial layer may comprise at least one electron beam, and wherein the apparatus may be configured to focus the electron beam on a diameter <2 nm at a kinetic energy of the electrons striking the sample (205, 300, 1500) of <3000 eV. The means for producing the first sacrificial layer may comprise at least one electron beam, and wherein the apparatus may be configured to focus the electron beam on a diameter <2 nm at a kinetic energy of the electrons striking the sample (205, 300, 1500) of <1500 eV.

The means for producing the first sacrificial layer may comprise at least one electron beam, and wherein the apparatus may be configured to focus the electron beam on a diameter <2 nm at a kinetic energy of the electrons striking the sample (205, 300, 1500) of <1000 eV.

The means for producing the first sacrificial layer may comprise at least one electron beam, and wherein the apparatus may be configured to focus the electron beam on a diameter <2 nm at a kinetic energy of the electrons striking the sample (205, 300, 1500) of <800 eV.

The means for producing the first sacrificial layer may comprise at least one electron beam, and wherein the apparatus may be configured to focus the electron beam on a diameter <2 nm at a kinetic energy of the electrons striking the sample (205, 300, 1500) of <600 eV.

Minimizing the focal diameter of the focused electron beam is accompanied by a reduction in the area in which local processing processes, i.e., etching processes or deposition processes, operate. A minimum focal diameter of <2 nm facilitates a minimum diameter of a local processing area of <10 nm. As a result of using electrons with a low kinetic energy for scanning the at least one reference mark and for processing the at least one defect, it is moreover possible to minimize the damage to the sample caused by the focused particle beam.

The local processing area of the focused particle beam of the apparatus may have a minimum diameter <10 nm.

The local processing area of the focused particle beam of the apparatus may have a minimum diameter <5 nm.

The local processing area of the focused particle beam of the apparatus may have a minimum diameter <4 nm.

The local processing area of the focused particle beam of the apparatus may have a minimum diameter <3 nm.

The local processing area of the focused particle beam of the apparatus may have a minimum diameter <2.5 nm.

The electron column may be configured to use a set of different apertures.

The apparatus may comprise a control device configured to control a beam current of the electron beam by selecting an aperture of the set of apertures. The apparatus may comprise a control device that is configured to determine the first reference distance and/or the second reference distance. Further, the control device can be configured to define a distance between the at least one first reference mark and the at least one defect such that the processing of the at least one defect and the scanning of the at least one first reference mark can be carried out without changing any parameters of the apparatus. Further, the control device can be configured to determine one or more sites on the sample where one or more first reference marks should be produced. Knowledge of the focal diameter of the focused particle beam allows the control device of the apparatus to determine a size of the first reference mark(s). The size of the first and the second reference marks firstly comprises the area of the reference mark(s) and secondly their height.

The apparatus can be configured to carry out the method steps of the method described above. The apparatus can also be designed as a computer system and include the aforementioned computer program.

In accordance with yet an exemplary embodiment of the present invention, this problem is solved by means of a method of embodiment 1 and an apparatus of embodiment 19. In embodiment 1 a method for repairing at least one defect of a sample using a focused particle beam comprises the steps of: (a) producing at least one first local, electrically conductive sacrificial layer on the sample, wherein the first local, electrically conductive sacrificial layer has a first portion and at least one second portion, wherein the first portion is adjacent to the at least one defect and wherein the first portion and the at least one second portion are electrically conductively connected to one another; and (b) producing at least one first reference mark on the at least one second portion of the first local, electrically conductive sacrificial layer for the purposes of correcting a drift of the focused particle beam in relation to the at least one defect while the at least one defect is being repaired.

Samples to be repaired frequently are electrical insulators or at best have semiconducting properties. Examples of the first group are the quartz substrates of photomasks or NIL stamps. Examples of the latter group are integrated circuits (ICs) to be produced on a wafer. A particle beam can generate electrical charges in the sample when a reference mark is scanned. This process may equally occur when scanning a defect to be repaired. As a result, different local electrostatic charges of a sample may be generated during a defect repair which is carried out with the aid of a drift correction.

When carrying out a method according to the invention, a focused particle beam generates electric charges (exclusively) in a first local, electrically conductive sacrificial layer. On account of the electrical conductivity of the first sacrificial layer, generated electric charges can be distributed uniformly over the first sacrificial layer. Consequently, a charged particle beam sees substantially the same electrostatic potential when scanning a reference mark and a defect. Different deflections of the charged particle beam when scanning over the defect and the reference mark, and hence different distortions of the image representation of the reference mark and the defect, are prevented. This can improve the quality of the drift correction, and hence the quality of the defect correction process.

The expression “substantially” here, as at other places in this description, denotes an indication of a measured variable within the customary error limits when using metrology according to the prior art.

In this application, the expression “local sacrificial layer” means that the sacrificial layer does not extend over the entire sample. Rather, the first sacrificial layer can be deposited around a defect or wholly or partly on a defect and around the latter with the aid of a local particle beam-induced deposition process. By way of example, the lateral extents of the local sacrificial layer can be less than 1 mm, less than 500 μm or less than 100 μm.

Both the first portion and the at least one second portion are electrically conductive in a first electrically conductive sacrificial layer. The electrical conductivities of the first portion, of the at least one second portion and of the connection(s) between the first and the at least one second portion can be the same or vary slightly. In this application, the term “electrically conductive” denotes a sacrificial layer with a specific electrical resistance of the order of metallic conductors, that is to say ρ<1 Ω·cm.

The adjacency of the first portion to the at least one defect may comprise at least one element from the following group: adjacency of the first portion to an edge of the at least one defect, partial coverage of the at least one defect by the first portion and complete coverage of the at least one defect by the first portion.

By virtue of the sacrificial layer edging the defect at the start of the repair process, a charged particle beam substantially “sees” the same electrostatic potential when scanning the at least one first reference mark and the defect to be repaired. Moreover, the first sacrificial layer edging the defect can effectively protect the sample from the influence of the repair process. By way of example, deposition material may inadvertently be deposited on the first sacrificial layer around the defect. Moreover, a first sacrificial layer which edges a defect of excess material to be repaired protects the region of the sample around the defect while a local etching process is carried out for the purposes of repairing the sample.

Once the repair process has been terminated, the first sacrificial layer can be removed from the sample together with the deposition material situated on said first sacrificial layer. As a result, carrying out a method according to the invention facilitates a correction of defects substantially without residue and consequently simultaneously facilitates a further increase in the quality of defect repair processes in addition to an improved drift correction.

The adjacency of the first portion to the edge of the at least one defect may comprise: adjacency of the first portion to an entire edge of the at least one defect. This embodiment is advantageous in particular for defects located in isolation on a sample.

The method may further comprise: determining at least one first reference distance between the at least one first reference mark and the at least one defect before the repair of the at least one defect has started.

In combination with the at least one first reference mark, the at least one first reference distance can be used to correct a drift of the at least one defect relative to the focused particle beam during a defect repair process.

The first portion may have a lateral extent around the at least one defect such that repairing the at least one defect substantially does not damage the sample.

The first portion of the first sacrificial layer represents a protective layer during a defect processing process or a defect repair process. The latter can be adapted, firstly, to the dimensions of the defect to be repaired and to the focal diameter of the particle beam used for the repair and, secondly, to the type of defect repair to be carried out. In the context above, the expression “substantially” means that no impairment of the functionality of the sample as a consequence of the implemented repair process can be substantiated following the defect repair.

A defect repair is preferably carried out within a field of view of the focused particle beam. This embodiment is advantageous in that the parameters of an apparatus that provides the particle beam do not need to be modified for the purposes of scanning the first reference mark during the repair process. This allows the best possible correction of a drift. By way of example, a field of view of a scanning particle microscope may comprise an area of 1000 μm×1000 μm, preferably 100 μm×100 μm, more preferably 10 μm×10 μm, and most preferably 6 μm×6 μm.

It is also possible that the lateral dimensions of the first sacrificial layer exceed the field of view of the focused particle beam. By way of example, this may occur in the case of large defects that are to be repaired. The first portion may have a lateral extent around the edge of the at least one defect which extends over a range of 1 nm to 1000 μm, preferably 2 nm to 200 μm, more preferably 5 nm to 40 μm, and most preferably 10 nm to 10 μm.

A thickness of the first portion may comprise a range of 0.1 nm to 1000 nm, preferably of 0.5 nm to 200 nm, more preferably of 0.5 nm to 200 nm and most preferably of 2 nm to 50 nm.

Producing the at least one reference mark may comprise: producing the at least one first reference mark at a distance from the at least one defect such that the repair of the at least one defect substantially does not influence the correction of the drift.

This feature ensures that the structure of a first reference mark remains substantially unchanged during a processing process. Therefore, the function of the first reference mark is maintained without restrictions throughout the entire repair process.

Producing the at least one first reference mark may comprise: producing the at least one first reference mark at a distance from the at least one defect such that the repair of the at least one defect substantially does not change the at least one first reference mark.

First reference marks which are used to correct a drift during a defect repair process and which are applied in the direct vicinity of a defect to be repaired may be modified by repair processes and thus may be impaired in their function as a means for drift correction. Firstly, material may be deposited on a first repair mark during a local deposition process and, secondly, a repair process in the form of an etching process may alter the structure of the first reference mark. The method described in this application allows the application of a first reference mark at a distance from the defect to be repaired, at which distance the repair process substantially does not change the at least one first reference mark.

The at least one first reference mark may comprise a lateral extent of 1 nm to 1000 nm, preferably of 2 nm to 500 nm, more preferably of 5 nm to 100 nm and most preferably of 10 nm to 50 nm. Moreover, a further demand in respect of the maximum extent of a reference mark emerges from the condition that the lateral extent of a reference mark must not be greater than the field of view of a scanning particle microscope.

The at least one first reference mark may comprise a height in the range of 1 nm to 1000 nm, preferably of 2 nm to 500 nm, more preferably of 5 nm to 200 nm and most preferably of 10 nm to 100 nm.

The first sacrificial layer may have a lateral extent determined by the lateral extent of the first portion and the number of at least one second portions.

The first portion and the at least one second portion may be interconnected in flush fashion. A flush connection between the first and the one or more second portions requires the greatest outlay for depositing a corresponding first sacrificial layer. Then again, a large-area first sacrificial layer has a high capacitance such that electrostatic charging caused by scanning the at least one reference mark and/or caused by a focused particle beam during the defect repair changes the electrostatic potential of the first sacrificial layer to only a small extent.

The electrically conductive connection between the first and the at least one second portion may comprise a width in the range of 0.1 nm to 1000 μm, preferably of 20 nm to 100 μm, more preferably of 30 nm to 10 μm and most preferably of 40 nm to 3 μm.

A thickness of an electrically conductive connection between the first and the at least one second portion may comprise a range of 0.1 nm to 1000 nm, preferably of 0.5 nm to 200 nm, more preferably of 1 nm to 100 nm and most preferably of 2 nm to 50 nm.

The connection of the first portion and the at least one second portion in the form of an electrically conductive connection may be advantageous when the first and the at least one second portion are at different levels. By way of example, the first portion may be arranged on the substrate of a photomask and the at least one second portion may be located on a pattern element of the photomask.

The focused particle beam may comprise at least one element from the following group: a photon beam, an electron beam, an ion beam, an atomic beam and a molecular beam. The photon beam may include a photon beam from the ultraviolet (UV), the deep ultraviolet (DUV) or the extreme ultraviolet (EUV) wavelength range.

Preferably the focused particle beam comprises a focused electron beam and/or a focused ion beam. Electron beams and ion beams can be focused on a much smaller spot than photon beams, and thus facilitate a greater spatial resolution during a defect repair. Moreover, electron beams and ion beams can be produced and imaged more easily than atomic beams or molecular beams.

Scanning a sample with a focused particle beam may cause damage in the scanned region of the sample. The extent of the damage occurring depends on the type of particle beam. For instance, an ion beam, an atomic beam or a molecular beam causes great damage in the scanned region as a result of the large momentum transfer from the massive particles to the lattice of the sample. Moreover, some of the particles of an ion, atomic or molecular beam are incorporated into the lattice of the sample, as a result of which its properties, for instance its optical properties, are locally modified.

By contrast, an electron beam—on account of the low electron mass—only typically makes very little damage in the scanned region of the sample. As a result, the use of electrons when repairing defects facilitates defect processing of a sample largely without side effects. Therefore, as a rule, the use of electrons should be preferred over the use of ions in a focused particle beam.

The at least one second portion may extend over at least one scanning region of the focused particle beam for the purposes of detecting the at least one first reference mark.

At least a majority of the particles of a focused particle beam may be incident on the at least one second portion of the first sacrificial layer while determining the position of the at least one first reference mark. A lateral extent of the at least one second portion may exceed the scanning region of the focused particle beam for scanning the at least one first reference mark by a factor of 1.2, preferably a factor of 1.5, more preferably a factor of 2 and most preferably a factor of 3.

What is ensured by virtue of the at least one second portion around the at least one first reference mark being greater by a defined factor than the scanning region scanned by the focused particle beam for the purposes of determining the position of the at least one first reference mark is that the scanning of the at least one first reference mark is implemented substantially completely on the first sacrificial layer, even in the case of a significant drift of the focused particle beam relative to the defect. This precludes an uncontrollable local generation of electrical charge carriers in the sample.

An additional degree of freedom is obtained by attaching the at least one first reference mark to a first sacrificial layer—rather than a direct deposition on the sample. Thus, the first sacrificial layer can be designed such that the latter can easily and substantially completely be removed from a sample at the end of a processing process of the sample. Untouched by this constraint, the at least one first reference mark can be designed such that the latter withstands both multiple determination of the position of the first reference mark and one or more extensive processing processes of the sample substantially unchanged.

By way of example, the area of the at least one second portion of the deposited first sacrificial layer can be square or rectangular. The lateral dimension relates to the shorter of the sides of a rectangle. The area of the at least one second portion can be adapted to the area of the scanning region of the at least one focused particle beam.

A lateral extent of the at least one second portion may have lateral dimensions in a range of 10 nm to 1000 μm, preferably 50 nm to 500 μm, more preferably 200 nm to 100 μm, and most preferably 500 nm to 50 μm.

A thickness of the at least one second portion may comprise a range of 0.1 nm to 1000 nm, preferably of 0.5 nm to 200 nm, more preferably of 1 nm to 100 nm and most preferably of 2 nm to 50 nm.

Producing the first sacrificial layer may comprise: depositing the first sacrificial layer by the focused particle beam in combination with at least one first precursor gas. The focused particle beam may comprise an electron beam.

The at least one first precursor gas may comprise: at least one first deposition gas for depositing the first portion of the first sacrificial layer, at least one second deposition gas for depositing the at least one second portion of the first sacrificial layer, and at least one third deposition gas for depositing the electrically conductive connection of the first sacrificial layer. The at least one first, the at least one second and the at least one third deposition gas may comprise a single deposition gas, two different deposition gases or three different deposition gases. The various functions of the first portion and of the one or more second portions and of the electrically conductive connection can be optimized by respectively adapted material compositions.

The at least one first precursor gas may comprise molybdenum hexacarbonyl (Mo(CO)₆) and nitrogen dioxide (NO₂) as an additive gas, and/or the first precursor gas may comprise chromium hexacarbonyl (Cr(CO)₆).

Producing the at least one first reference mark may comprise: depositing the at least one first reference mark using a focused particle beam in combination with at least one second precursor gas. The focused particle beam for depositing the at least one first reference mark may comprise an electron beam.

The first sacrificial layer and the at least one first reference mark may be deposited using one particle beam or using different particle beams. By way of example, the first sacrificial layer may be deposited using an electron beam and the at least one second reference mark may be deposited using an ion beam.

The at least one first precursor gas for depositing the first sacrificial layer may comprise at least one element from the following group: metal alkyls, transition element alkyls, main group alkyls, metal carbonyls, transition element carbonyls, main group carbonyls, metal alkoxides, transition element alkoxides, main group alkoxides, metal complexes, transition element complexes, main group complexes and organic compounds.

The at least one second precursor gas for depositing the at least one reference mark may comprise at least one element from the following group: metal alkyls, transition element alkyls, main group alkyls, metal carbonyls, transition element carbonyls, main group carbonyls, metal alkoxides, transition element alkoxides, main group alkoxides, metal complexes, transition element complexes, main group complexes and organic compounds.

The metal alkyls, transition element alkyls and main group alkyls may comprise at least one element from the following group: cyclopentadienyl (Cp) trimethyl platinum (CpPtMe₃), methylcyclopentadienyl (MeCp) trimethyl platinum (MeCpPtMe₃), tetramethyltin (SnMe₄), trimethylgallium (GaMe₂), ferrocene (Co₂Fe) and bisarylchromium (Ar₂Cr). The metal carbonyls, transition element carbonyls and main group carbonyls may comprise at least one element from the following group: chromium hexacarbonyl (Cr(CO)₆), molybdenum hexacarbonyl (Mo(CO)₆), tungsten hexacarbonyl (W(CO)₆), dicobalt octacarbonyl (Co₂(CO)₈), triruthenium dodecacarbonyl (Ru₃(CO)₁₂) and iron pentacarbonyl (Fe(CO)₅). The metal alkoxides, transition element alkoxides and main group alkoxides may comprise at least one element from the following group: tetraethyl orthosilicate (TEOS, Si(OC₂H₅)₄) and tetraisopropoxytitanium (Ti(OC₃H₇)₄). The metal halides, transition element halides and main group halides may comprise at least one element from the following group: tungsten hexafluoride (WF₆), tungsten hexachloride (WCl₆), titanium hexachloride (TiCl₆), boron trichloride (BCl₃) and silicon tetrachloride (SiCl₄). The metal complexes, transition element complexes and main group complexes may comprise at least one element from the following group: copper bis(hexafluoroacetylacetonate) (Cu(C₅F₆HO₂)₂) and dimethylgold trifluoroacetylacetonate (Me₂Au(C₅F₃H₄O₂)). The organic compounds may comprise at least one element from the following group: carbon monoxide (CO), carbon dioxide (CO₂), aliphatic hydrocarbons, aromatic hydrocarbons, constituents of vacuum pump oils and volatile organic compounds.

Producing the at least one first reference mark may comprise: etching at least one depression into the at least one second portion of the first sacrificial layer. Etching the at least one depression may comprise: carrying out a local etching process using a focused particle beam in combination with at least one third precursor gas. The focused particle beam may comprise an electron beam and/or an ion beam.

The at least one third precursor gas may comprise at least one etching gas. The at least one etching gas may comprise one element from the following group: a halogen-containing compound and an oxygen-containing compound. The halogen-containing compound may comprise at least one element from the following group: fluorine (F₂), chlorine (Cl₂), bromine (Br₂), iodine (I₂), xenon difluoride (XeF₂), dixenon tetrafluoride (Xe₂F₄), hydrofluoric acid (HF), hydrogen iodide (HI), hydrogen bromide (HBr), nitrosyl chloride (NOCl), phosphorus trichloride (PCl₃), phosphorus pentachloride (PCl₅) and phosphorus trifluoride (PF₃). The oxygen-containing compound may comprise at least one element from the following group: oxygen (O₂), ozone (O₃), water vapour (H₂O), hydrogen peroxide (H₂O₂), nitrous oxide (N₂O), nitrogen oxide (NO), nitrogen dioxide (NO₂) and nitric acid (HNO₃).

The at least one first, the at least one second and/or the at least one third precursor gas may comprise at least one additive gas from the following group: an oxidizing agent, a halide and a reducing agent.

The oxidizing agent may comprise at least one element from the following group: oxygen (O₂), ozone (O₃), water vapor (H₂O), hydrogen peroxide (H₂O₂), nitrous oxide (N₂O), nitrogen oxide (NO), nitrogen dioxide (NO₂) and nitric acid (HNO₃). The halide may comprise at least one element from the following group: chlorine (Cl₂), hydrochloric acid (HCl), xenon difluoride (XeF₂), hydrofluoric acid (HF), iodine (I₂), hydrogen iodide (HI), bromine (Br₂), hydrogen bromide (HBr), nitrosyl chloride (NOCl), phosphorus trichloride (PCl₃), phosphorus pentachloride (PCl₅) and phosphorus trifluoride (PF₃). The reducing agent may comprise at least one element from the following group: hydrogen (H₂), ammonia (NH₃) and methane (CH₄).

The first precursor gas may comprise molybdenum hexacarbonyl (Mo(CO)₆) and the at least one additive gas may comprise nitrogen dioxide (NO₂), and/or the second precursor gas may comprise tetraethyl orthosilicate (Si(OC₂H₅)₄) or chromium hexacarbonyl (Cr(CO)₆).

The above-described method may further comprise: removing the part of the first portion of the first sacrificial layer which covers the at least one defect, before the at least one defect is repaired.

Removing the first portion of the first sacrificial layer which covers the at least one defect may comprise: carrying out a particle beam-induced etching process using at least one fourth precursor gas. The at least one fourth precursor gas may comprise at least one second etching gas. The at least one second etching gas may comprise at least one element from the group of the first etching gases listed above. The first deposition gas for depositing the first portion of the sacrificial layer may comprise an element from the group of: chromium hexacarbonyl (Cr(CO)₆) and molybdenum hexacarbonyl (Mo(CO)₆), and the at least one second etching gas for removing the first portion of the sacrificial layer may comprise nitrosyl chloride (NOCl), on its own or in combination with at least one additive gas, for instance water (H₂O).

The precursor gas for etching at least one first reference mark into the at least one second portion of the first sacrificial layer may comprise xenon difluoride (XeF₂) in combination with an additive gas, for example oxygen (O₂), water (H₂O) or chlorine (Cl₂). Alternatively, e.g. nitrosyl chloride (NOCl), on its own or in combination with an additive gas, for instance water (H₂O), may be used for generating a first reference mark.

The at least one defect may comprise a defect of excess material and the method may further comprise: repairing the at least one defect at least partly through the first sacrificial layer.

A first sacrificial layer or a first portion of a first sacrificial layer which partly or fully extends over a defect of excess material to be repaired may be removed in a single process step from the sample, for example using a local particle beam-induced etching process. In this case, the etching gas and/or an additive gas can be adapted to the progress of the etching process—if the etching rates of the defect and of the material of the first portion of the first sacrificial layer differ significantly from one another. Moreover, it is possible to adapt further beam parameters of the particle beam and/or further process parameters to the progress of the etching process. The progress of the local etching process can be determined by analyzing the backscattered or secondary electrons generated during the etching process. Moreover, or alternatively, the material of the removed material can be analyzed, for instance by way of a SIMS (secondary ion mass spectroscopy) analysis. To this end, an ion beam is preferably used as a particle beam. Further, the etching rates can be calibrated by virtue of the etching processes of the sacrificial layer and for the material to be removed being optimized separately from one another. By way of example, this can be implemented by carrying out etching sequences.

The first and the at least one second portion of the first sacrificial layer may have lateral extents such that the action of repairing the at least one defect distorts an image section comprising the at least one defect by no more than 10%, preferably by no more than 5%, more preferably by no more than 2% and most preferably by no more than 1%. The action of repairing a defect with the aid of a focused particle beam may lead to electrostatic charging of the electrically conductive sacrificial layer. The electrostatic charging of the sacrificial layer may lead to a distortion of the image section containing the defect or a defect residue. The distortion of the image section is related to the image section before the repair process has started.

Electrostatic charging of the sacrificial layer may locally influence imaging parameters of the focused particle beam and said imaging parameters may consequently be subject to local variations. A local change, for instance a local variation of the magnification of an image produced with the aid of a scanning focused particle beam, results in a distortion of the image in comparison with an image whose magnification has no local variation of the imaging parameters, for example the magnification.

The first portion, the at least one second portion and the electrically conductive connection may have a material composition which comprises at least one element from the following group: a metal, a metal-containing compound, a conductive ceramic and a doped semiconductor compound.

The metal may comprise at least one element from the following group: molybdenum, cobalt, chromium, niobium, tungsten, rhenium, ruthenium and titanium. The metal-containing compound may comprise at least one element from the following group: a molybdenum alloy, a cobalt-containing compound, a chromium-containing compound, a niobium-containing compound, a tungsten-containing compound, a rhenium-containing compound and a titanium-containing compound. The metal-containing compound may comprise elements from the following group: nitrogen, oxygen, fluorine, chlorine, carbon and silicon. The doped semiconductor compound may comprise at least one element from the following group: indium tin oxide (ITO), aluminum-doped zinc oxide (AZO), antimony-doped tin oxide (ATO), and fluorine-doped tin oxide (FTO). The conductive ceramic may comprise molybdenum silicide.

The first portion, the at least one second portion and the electrically conductive connection may have different material compositions.

The first sacrificial layer and the at least one first reference mark may have different material compositions.

In addition to the topology contrast of the first reference mark, this also yields a material contrast between the at least one second portion of the first sacrificial layer and the at least one first reference mark when the at least one first reference mark is scanned.

The at least one defect may comprise a defect of excess material and the action of repairing the at least one defect may comprise: choosing a material composition of the first portion of the first sacrificial layer, of the at least one second etching gas, and/or of the at least one additive gas such that an etching rate of an etching process induced by a focused particle beam is substantially the same for the at least one defect and the first portion.

The rounding of curves at the edge of the etching region, which occurs in the case of local etching of a defect, can be minimized by satisfying this condition. Further, under-etching of the sample within the scope of a defect correction can be avoided. At the same time, observing this condition facilitates the production of maximally steep side walls of an etched region of the sample.

A sample may comprise a lithographic sample. The lithographic sample may comprise at least one element from the following group: a photomask and a stamp for nanoimprint lithography (NIL). However, a sample may also comprise at least one element from the following group: a photomask, a stamp for NIL, an integrated circuit (IC), a photonic integrated circuit (PIC), a microsystem (a MEMS, micro-electromechanical system, or a MOEMS, a micro-optoelectromechanical system) and a printed circuit board (PCB). The integrated circuit and/or the photonic integrated circuit may be arranged on a wafer. A photomask may be any type of transmissive or reflective photomask, for example a binary or a phase-shifting mask.

The method may further comprise: scanning the sample with the focused particle beam for the purposes of producing a defect map of the sample.

Scanning the sample may comprise scanning the at least one defect of the sample using a focused particle beam. The focused particle beam for scanning the sample may comprise the particle beam used to produce the first sacrificial layer, to generate the at least one first reference mark and/or to initiate a local defect processing process. However, it is also possible within the scope of scanning the sample to use a first particle beam, for instance a photon beam, to identify the at least one defect and to use a second particle beam, for example an electron beam, to detect a contour of a repair shape of the at least one defect.

The apparatus which carries out the above-described method may receive the coordinates of the at least one defect of the sample from a sample inspection apparatus. The defect map of the sample may include the at least one defect of the sample. In particular, the defect map may include a repair shape for repairing the at least one defect.

The method may further comprise: producing at least one second reference mark on the sample and determining at least one second reference distance between the at least one second reference mark and the at least one defect before the production of the first sacrificial layer has started.

Further, the method may comprise: producing at least one second sacrificial layer on the sample, depositing at least one second reference mark on the at least one second sacrificial layer and determining at least one second reference distance between the at least one second reference mark and the at least one defect before the production of the first sacrificial layer has started.

The at least one second reference mark is required to correct a drift during the deposition of the first sacrificial layer. Further, the at least one second reference mark is required for correcting a drift during the removal of the first portion of the first sacrificial layer which covers the at least one defect. Therefore, for reasons of process economy, it may be advantageous to dispense with the deposition of the at least one second sacrificial layer and apply the second reference mark(s) directly to the sample. Then again, the deposition of the at least one second sacrificial layer provides an additional degree of freedom which can be used to simplify the removal of the at least one second reference mark from the sample.

The at least one second reference distance may be greater than the at least one first reference distance.

The at least one second reference distance and the at least one second reference mark are required to correct a drift between the focused particle beam and the at least one defect while the first sacrificial layer is deposited. It is therefore very advantageous if the at least one second reference mark is not covered by the first sacrificial layer. This ensures the function of the at least one second reference mark.

Moreover, the method may comprise: correcting a drift while implementing at least one element from the following group: producing the first sacrificial layer and removing a first portion of the first sacrificial layer which covers the at least one defect from the at least one defect by using the at least one second reference mark and the at least one second reference distance.

The duration of the process processing can be optimized by virtue of the first sacrificial layer being deposited as precisely as possible in relation to the defect to be repaired. By way of example, should it be possible to deposit the first sacrificial layer around the defect without substantially covering the latter, it is possible to dispense with the etching process for removing the first portion of the first sacrificial layer for the purposes of exposing the defect prior to the repair thereof.

The method may further comprise: jointly removing the first sacrificial layer and the at least one first reference mark from the sample within the scope of a wet chemical and/or mechanical cleaning process.

It is an advantage of the method described here that the at least one first reference mark can be removed, together with the first sacrificial layer, from the sample in a standard cleaning process. The method further allows matching of the material composition of the first sacrificial layer to the sample such that the first sacrificial layer can fully fulfil its various functions during a defect processing process and, moreover, can easily be removed from the sample once the defect repair has been terminated.

Moreover, the method may comprise: jointly removing the first sacrificial layer, the at least one reference mark and the at least one first reference mark from the sample within the scope of a wet chemical cleaning process.

The method may additionally comprise: jointly removing the first sacrificial layer, the at least one second sacrificial layer, the at least one first reference mark and the at least one second reference mark from the sample within the scope of a wet chemical and/or mechanical cleaning process.

The wet chemical cleaning process can be carried out using water and at least one oxidizing gas dissolved therein. The oxidizing gas may comprise at least one element from the following group: oxygen (O₂), nitrogen (N₂) and hydrogen (H₂). Furthermore, it is possible for an aqueous cleaning solution to have a pH value 5, preferably <3.5, more preferably <2 and most preferably <1.

The mechanical cleaning process may comprise the application of ultrasound and/or megasound. Cleaning by exerting the action of a physical force on the region of the samples to be cleaned is also possible.

Further, the method may comprise: jointly removing the first sacrificial layer and the at least one first reference mark from the sample by use of a focused particle beam-induced etching process. Moreover, it is conceivable to use a particle beam, for example a photon beam, to remove the first sacrificial layer and the at least one first reference mark.

The method may additionally comprise: jointly removing the first sacrificial layer, the at least one first reference mark and the at least one second reference mark from the sample by use of an etching process induced by a focused particle beam.

The method may moreover comprise: jointly removing the first sacrificial layer, the at least one second sacrificial layer, the at least one first reference mark and the at least one second reference mark from the sample with the aid of an etching process induced by a focused particle beam.

With the aid of a local etching process which is induced by a focused particle beam, it is also possible to remove the at least one first reference mark, the at least one second reference mark from the sample together with the first sacrificial layer and/or the at least one second sacrificial layer. The focused particle beam for removing the first and/or the second reference mark(s) and the first and/or the second sacrificial layer(s) can be the particle beam that is used to produce the reference mark(s) and/or the sacrificial layer(s). Moreover, the focused particle beam can be the particle beam used to carry out the defect processing. The material composition of the sacrificial layer(s) can be chosen from the viewpoint of simple removability, for instance a simple etchability of the sacrificial layer(s) by a local particle beam-induced etching process. The preferred particle beam for joint removal of the sacrificial layer(s) and the reference mark(s) comprises an electron beam.

It is an advantage of the method described in this application that both the sacrificial layer(s) and the reference mark(s) can be generated using a single apparatus and the apparatus can simultaneously be used to process the at least one defect and remove the sacrificial layer(s) together with the associated reference mark(s). This means there is no need during the entire defect repair process to break the vacuum prevalent in the apparatus.

A sample may have at least one defect, which is repaired using the method described above.

A computer program can comprise instructions that prompt a computer system to carry out the method steps explained above. The computer program can be stored in a computer-readable storage medium.

In embodiment 19, an apparatus for repairing at least one defect of a sample using a focused particle beam comprises: (a) means for producing at least one first local, electrically conductive sacrificial layer on the sample, wherein the first local, electrically conductive sacrificial layer has a first portion and at least one second portion, wherein the first portion is adjacent to the at least one defect and wherein the first portion and the at least one second portion are electrically conductively connected to one another; and (b) means for producing at least one first reference mark on the at least one second portion of the first local, electrically conductive sacrificial layer for the purposes of correcting a drift of the focused particle beam in relation to the at least one defect while the at least one defect is being repaired.

The means for producing the first sacrificial layer can comprise at least one electron beam and the apparatus can be configured to focus the electron beam on a diameter <2 nm in the case of a kinetic energy of the electrons striking the sample of <3000 eV, preferably <2000 eV, more preferably <1000 eV, and most preferably <600 eV.

Minimizing the focal diameter of the focused electron beam is accompanied by a reduction in the area in which local processing processes, i.e., etching processes or deposition processes, operate. A minimum focal diameter of <2 nm facilitates a minimum diameter of a local processing area of <10 nm. As a result of using electrons with a low kinetic energy for scanning the at least one reference mark and for processing the at least one defect, it is moreover possible to minimize the damage to the sample caused by the focused particle beam.

The apparatus can be configured to carry out the method steps of the method described above. The apparatus can also be designed as a computer system and include the aforementioned computer program.

The apparatus may comprise an electron column with a single-stage condenser system. Further, the electron column may be configured to use a set of different stops. The beam current can be controlled by way of the choice of stop. The single-stage condenser system may be configured to focus low kinetic energy electrons on a small spot. A work distance between an output of the electron column and a sample can be less than 5 mm, preferably less than 4 mm, more preferably less than 3 mm and most preferably less than 2.5 mm.

The apparatus can comprise a control device that is configured to determine the first reference distance and/or the second reference distance. Further, the control device can be configured to define a distance between the at least one first reference mark and the at least one defect such that the processing of the at least one defect and the scanning of the at least one first reference mark can be carried out without changing any parameters of the apparatus. Further, the control device can be configured to determine one or more sites on the sample where one or more first reference marks should be produced. Knowledge of the focal diameter of the focused particle beam allows the control device of the apparatus to determine a size of the first reference mark(s). The size of the first and the second reference marks firstly comprises the area of the reference mark(s) and secondly their height.

### DESCRIPTION OF THE DRAWINGS

The detailed description that follows describes currently preferred exemplary embodiments of the invention with reference to the drawings, wherein:

FIG. 1A presents a schematic section through a local defect processing process of a sample in the form of a particle beam-induced etching process according to the prior art;

FIG. 1B reproduces the result of the defect processing process from FIG. 1A;

FIG. 2 schematically represents a block diagram of some important components of an apparatus that can be used to very precisely repair a defect of a sample;

FIG. 3A schematically represents a plan view of a section of a substrate of a photomask, which shows a defect, four second sacrificial layers, four second reference marks with associated scanning regions for a focused particle beam and four second reference distances between the second reference marks and the defect;

FIG. 3B shows a modification of FIG. 3A, in which the reference marks are deposited directly on the substrate or the pattern element of the photomask;

FIG. 4 reproduces the section from FIG. 3A, on which a first exemplary embodiment of a first sacrificial layer has been deposited, the first sacrificial layer having a first portion that covers the defect and a second portion on which four first reference marks are produced;

FIG. 5 reproduces the section from FIG. 3A, on which a second exemplary embodiment of a first sacrificial layer has been deposited, the first sacrificial layer having a first portion that covers the defect and its surroundings, and four second portions each with a first reference mark deposited thereon;

FIG. 6 represents FIG. 5 following the exposure of the defect by carrying out a local particle beam-induced etching process on the first portion of the first sacrificial layer;

FIG. 7 reproduces FIG. 6, with additionally the first reference distances between the first reference marks and the defect being elucidated;

FIG. 8 renders FIG. 7 at the end of the defect processing process;

FIG. 9 illustrates the repaired section from FIG. 3A following the removal of the first sacrificial layer and the four second sacrificial layers, together with the associated four first and four second reference marks;

FIG. 10 shows a section of a stamp for nanoimprint lithography with a first thick sacrificial layer, through which a particle beam-induced etching process is carried out;

FIG. 11 represents FIG. 10 with a second thin sacrificial layer;

FIG. 12 represents measurement data relating to the width or the diameter of the generated depression at a depth corresponding to 10% of the nominal depth as a function of the etching depth, for the particle beam-induced etching processes elucidated in FIGS. 10 and 11 and for a comparison process without sacrificial layer;

FIG. 13 reproduces FIG. 12, with the diameter of the etched depression being measured at 50% of the nominal etching depth;

FIG. 14 presents measurement data relating to the side wall angle of the etching processes of FIGS. 10 and 11 and of a comparison process without sacrificial layer;

FIG. 15 shows the result of a particle beam-induced etching process of an NIL stamp through a sacrificial layer, the sacrificial layer being etched with a greater rate than the material of the stamp;

FIG. 16 repeats FIG. 15, with the etching rate for the sacrificial layer being less than the etching rate for the material of the stamp;

FIG. 17 repeats FIG. 15, with the etching rates for the sacrificial layer and for the stamp being substantially the same; and

FIG. 18 reproduces a flowchart of a method for repairing at least one defect of a sample.

### DETAILED DESCRIPTION

Currently preferred embodiments of a method according to the invention and of an apparatus according to the invention for repairing samples are explained below. The method is described with reference to photomasks and stamps for nanoimprint lithography (NIL). Further, an apparatus according to the invention is explained using the example of a modified scanning electron microscope, which can be used to repair defects of photolithographic masks or templates for NIL.

However, a method according to the invention and an apparatus according to the invention are not restricted to the examples described below. As will be recognized without difficulty by a person skilled in the art, instead of the scanning electron microscope discussed it is possible to employ any scanning particle microscope which uses for example a focused ion beam and/or a focused photon beam as energy source for initiating a local deposition process and/or etching process. Further, the method according to the invention is not restricted to the use of the samples in the form of photomasks and NIL stamps discussed by way of example below. Rather, it can be used to repair the embodiments of any sample listed in exemplary fashion in the sections above.

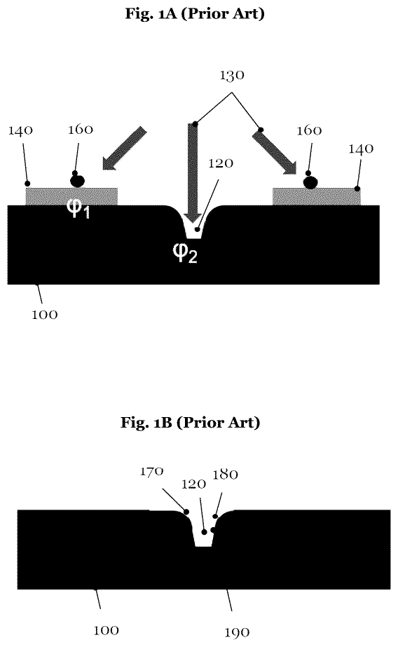

FIG. 1A represents a schematic section through a repair process of a defect 120 of a sample 100 according to the prior art. In the example depicted in FIG. 1A, the sample 100 comprises a wafer 100, into which a missing depression is intended to be etched. That is to say, the sample 100 has a defect 120 of excess material. Two reference marks 160 have been deposited on the sample 100 for the purposes of controlling a drift of a focused particle beam 130 relative to the sample 100 during an etching process for producing the depression. To protect the sample 100 against damage caused when scanning the reference marks 160 with the particle beam 130, the reference marks 160 have been deposited on sacrificial layers 140. The reference marks 160 are referred to as DC (drift correction) marks in the art.

Electric charges that cause an electrostatic potential φ₁ may be generated on the surface of the sample 100 when the latter is scanned using a particle beam. Equally, electric charges that may lead to electrostatic charging φ₂ of the sacrificial layers 140 may be produced or implanted in the sacrificial layers 140 when the reference marks 160 are scanned using a particle beam 130 The electrostatic charging of the sacrificial layers 140 leads to a first deflection of a charged particle beam 130, for example an electron beam 130, when scanning the sample 100 and to second deflection of said beam when scanning the sacrificial layers 140 or the reference marks 160.

The problem of local electrostatic charging φ₂ of the sample 100 likewise occurs when scanning the defect 120 using a focused particle beam 130 and when carrying out a particle beam-induced etching process for the purposes of correcting the defect 120. Typically, the electrostatic charging φ₂ of the sacrificial layers 140 differs from the local charging pi of the sample 100. Accordingly, a charged particle beam 130 is deflected differently when scanning the sample 100 in the region of the defect 120 than when scanning the sacrificial layers 140 for the purposes of detecting the reference marks 160.

FIG. 1B schematically shows the result of the defect repair process from FIG. 1A. Firstly, the action on the edge 170 around the defect 120 of the particle beam-induced local etching process carried out for defect correction leads to a rounding 180 of the edge 170 of the sample 100 around the repaired defect 120. Secondly, the side wall angle 190 generated by the defect repair differs significantly from a specified side wall angle of 90°.

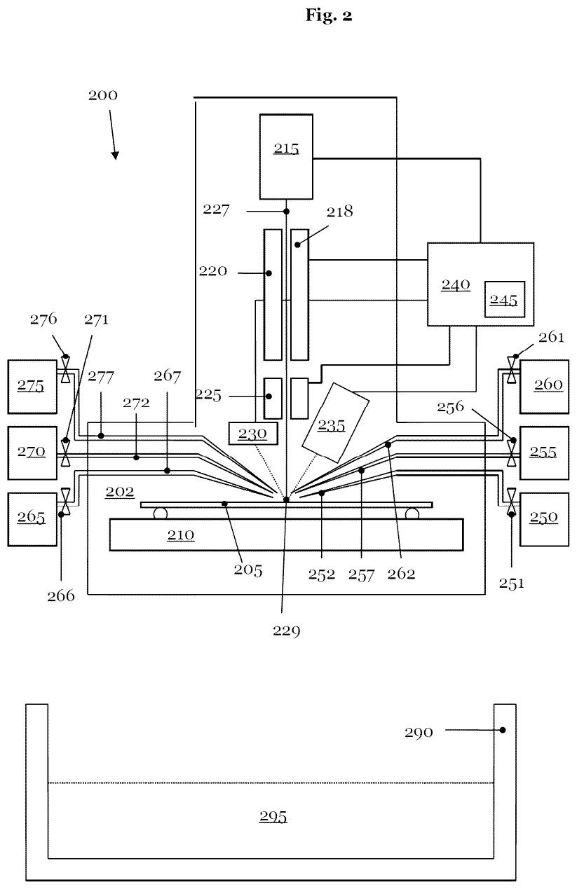

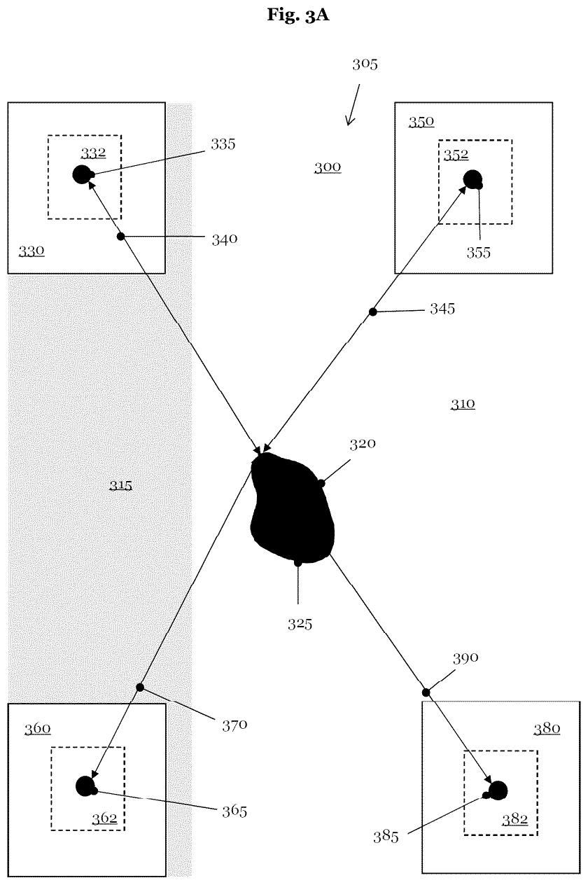

The apparatus 200 described below allows repair processes to be carried out with improved results in comparison with FIG. 1B. FIG. 2 schematically shows essential components of a device 200 which can be used for analyzing and/or repairing samples 205. The sample 205 may be any microstructured component or structural part. By way of example, the sample 205 may comprise a transmissive photomask, a reflective photomask or a template for NIL. Furthermore, the apparatus 200 may be used for analyzing and/or repairing for example an integrated circuit (IC), a microscopic system (MEMS, MOEMS) and/or a photonic integrated circuit (PIC). In the examples explained below, the sample 205 is a photolithographic mask or an NIL stamp.

The exemplary apparatus 200 in FIG. 2 is a modified scanning electron microscope (SEM). An electron gun 215 produces an electron beam 227, which is directed by the beam shaping elements 220 and beam deflecting elements 225 as a focused electron beam 227 onto the sample 205 arranged on a sample stage 210.

The beam shaping elements 220 include a single-stage condenser system 218. The single-stage condenser system 218 facilitates production of a focused electron beam 227 on the sample 205 with a very small spot diameter on the sample 205 (D<2 nm) while simultaneously having a lower kinetic energy of the electrons of the electron beam 227 on the sample 205 (E<1 keV). The SEM has a small working distance from the sample 205 for the purposes of producing the small spot diameter on the sample 205. The working distance may have dimensions below 3 mm. The low energy electrons facilitate virtually damage-free processing of the sample 205 with a very high spatial resolution. However, the low kinetic energy of the electrons of the electron beam 227 renders the latter particularly sensitive to unwanted deflections on account of electrostatic charging of the sample 100 φ₂ and/or of the sacrificial layers 160 φ₁. The measures described in the following figures avoid this problem.

Moreover, the beam shaping elements 220 include a set of different stops. The beam current of the electron beam 227 is controlled by way of the choice of the appropriate stop.

The sample stage 210 has micro-manipulators (not shown in FIG. 2) with the aid of which a defective site 120 on the sample 205 can be brought beneath the point of incidence of the electron beam 229 on the sample 205. In addition, the sample stage 210 can be displaced in height, i.e., in the beam direction of the electron beam 227, such that the focus of the electron beam 227 comes to rest on the surface of the sample 205 (likewise not illustrated in FIG. 2). Furthermore, the sample stage 210 can comprise an apparatus for setting and controlling the temperature, which makes it possible to bring the sample 205 to a specified temperature and keep it at this temperature (not indicated in FIG. 2).

The apparatus 200 in FIG. 2 uses an electron beam 227 as energy source 215 for initiating a local chemical reaction on the sample 205. As explained above, electrons that are incident on the surface of the sample 205 cause less damage on the sample 205 in comparison with an ion beam for example, even if their kinetic energy varies over a large energy range. However, the apparatus 200 and the method presented here are not restricted to the use of an electron beam 227. Rather, any desired particle beam 227 can be used which is able to bring about locally a chemical reaction of a precursor gas at the point of incidence 229 of the particle beam 227 on the surface of the sample 205. Examples of alternative particle beams are an ion beam, an atomic beam, a molecular beam and/or a photon beam. Furthermore, it is possible to use two or more particle beams in parallel. In particular, it is possible simultaneously to use an electron beam 227 and a photon beam as energy source 215 (not shown in FIG. 2).

The electron beam 227 can be used for recording an image of the sample 205, for instance a photomask, in particular of a defective site 120 of the sample 205 of a photomask. A detector 230 for detecting backscattered electrons and/or secondary electrons supplies a signal that is proportional to the surface contour and/or composition of the sample 205.

By scanning the electron beam 227 over the sample 205 with the aid of a control device 245, a computer system 240 of the apparatus 200 can generate an image of the sample 205. The control device 245 may be part of the computer system 240, as illustrated in FIG. 2, or may be executed as a separate unit (not illustrated in FIG. 2). The computer system 240 can comprise algorithms which are realized in hardware, software, firmware or a combination thereof and which make it possible to extract an image from the measurement data of the detector 230. A screen of the computer system 240 (not shown in FIG. 2) can represent the calculated image. Furthermore, the computer system 240 can store the measurement data of the detector 230 and/or the calculated image. In addition, the control unit 245 of the computer system 240 may control the electron gun 215, the beam imaging and beam shaping elements 220 and 225, and the single-stage condenser system 218. Control signals of the control device 245 can furthermore control the movement of the sample stage 210 by use of the micro-manipulators (not indicated in FIG. 2).

The apparatus 200 may comprise a second detector 235. The second detector 235 can be used to detect the energy distribution of the secondary electrons emitted by the sample 205. Hence, the detector 235 allows the composition of the material removed from the sample 205 in a local etching process to be analyzed. The detector 235 can comprise a SIMS (secondary ion mass spectroscopy) detector in an alternative embodiment.

The electron beam 227 incident on the sample 205, or in general a focused particle beam 227, may electrostatically charge the sample 205. As a result, the electron beam 227 can be deflected and the spatial resolution when recording a defect 120 and/or when repairing the latter can be reduced. Moreover, the micro-manipulators used to align the sample 205 with respect to a region of the sample 205 to be analyzed and/or repaired by the electron beam 227 may be subject to a drift. To reduce the effect of local electrostatic charging of the sample 205 and/or of a thermal drift, the apparatus 200 comprises supply containers for applying sacrificial layers 140 and reference marks 160 to the sample 205, which allow the above-described disadvantageous effects to be largely avoided during the analysis, that is to say the examination and/or the action of repairing the sample 205.

The apparatus 200 comprises a first container 250 storing a first precursor gas for the purposes of depositing a sacrificial layer 140. To this end, the first container may store a metal carbonyl for example, for instance molybdenum hexacarbonyl (Mo(CO)₆).

The second supply container 255 may store a second precursor gas which can be used for producing reference marks 160. By way of example, the second precursor gas may store tetraethyl orthosilicate (TEOS, Si(OC₂H₅)₄) or chromium hexacarbonyl (Cr(CO)₆). In an alternative embodiment, the second supply container 255 may store a second precursor gas in the form of a first etching gas, which facilitates the production of first reference marks in the form of local depressions in a second portion of a first sacrificial layer. Further, the first etching gas can be used to remove the part of a first sacrificial layer covering a defect to be repaired. The first etching gas may comprise xenon difluoride (XeF₂), in combination with an additive gas, for instance oxygen (O₂) or chlorine (Cl₂). Alternatively, the first etching gas may comprise nitrosyl chloride (NOCl).

A third supply container 260 may store an additive gas, for example a halide, for instance chlorine (Cl₂), a reducing agent, for example ammonia (NH₃), or an oxidizing agent, for instance nitrogen dioxide (NO₂) or water (H₂O). An additive gas can be used to assist the deposition of a sacrificial layer 140 and/or to assist the generation of reference marks 160. Moreover, the additive gas of the third gas storage unit 260 can be used to expose the defect after producing a first sacrificial layer. It is preferable to use the nitrogen dioxide (NO₂) additive gas for depositing sacrificial layers and/or the water (H₂O) additive gas for carrying out etching processes.

In order to process the sample 205 arranged on the sample stage 210, i.e., to repair the defect(s) 120 of said sample, the apparatus 200 comprises at least three supply containers for at least a third and a fourth precursor gas. In the exemplary apparatus 200 of FIG. 2, the third precursor gas stored in the fourth container 265 may comprise three different processing gases. These can be used to deposit the first portion, the at least one second portion and the electrically conductive connection between the first and the at least one second portion of the first sacrificial layer.

Further, the fourth supply container 265 may store a third precursor gas in the form of a further deposition gas. The latter is used to deposit missing material on the sample 205 with the aid of an electron beam-induced deposition (EBID) process. Unlike the material of the sacrificial layer 140, for instance, the material deposited from the fourth supply container should exhibit very good adherence to the sample 205 and reproduce the physical and optical properties of the latter to the best possible extent. By way of example, a main group alkoxide, for instance TEOS, or a metal carbonyl, for instance molybdenum hexacarbonyl (Mo(CO)₆) or chromium hexacarbonyl (Cr(CO)₆), can be stored in the fourth supply container 265.

The fifth supply container 270 may store a fourth precursor gas in the form of a second etching gas. The second etching gas of the fifth supply container 270 can be used to remove excess material from the sample 205 with the aid of a local electron beam-induced etching (EBIE) process. Xenon difluoride (XeF₂) is an example of a frequently used etching gas. Should the defect comprise a material that is difficult to etch, the second etching gas may comprise nitrosyl chloride (NOCl).

The sixth supply container 275 can store a further precursor gas, for instance a further deposition gas or a third etching gas. In a further embodiment, the sixth supply container may store a second additive gas.

In the exemplary apparatus 200 from FIG. 2, each supply container 250, 255, 260, 265, 270, 275 has its own control valve 251, 256, 261, 266, 271, 276, in order to monitor or control the absolute value of the corresponding gas that is provided per unit time, i.e., the gas volumetric flow rate at the site of the incidence of the electron beam 227. The control valves 251, 256, 261, 266, 271 and 276 are controlled and monitored by the control unit 245 of the computer system 240. The partial pressure ratios of the gases provided at the processing location 229 can thus be set in a wide range.

Furthermore, in the exemplary apparatus 200 each supply container 250, 255, 260, 265, 270, 275 has its own gas feed line system 252, 257, 262, 267, 272, 277, which ends with a nozzle in the vicinity of the point of incidence of the electron beam 227 on the sample 205. In an alternative embodiment (not represented in FIG. 2), a gas feed line system is used to bring a plurality or all of the processing gases in a common stream onto the surface of the sample 205.

In the example illustrated in FIG. 2, the valves 251, 256, 261, 266, 271, 276 are arranged in the vicinity of the corresponding containers 250, 255, 260, 265, 270, 275. In an alternative arrangement, the control valves 251, 256, 261, 266, 271, 276 can be incorporated in the vicinity of the corresponding nozzles (not shown in FIG. 2). Unlike the illustration shown in FIG. 2 and without preference at the present time, it is also possible to provide one or more of the gases stored in the containers 250, 255, 260, 265, 270, 275 non-directionally in the lower part of the vacuum chamber 202 of the apparatus 200. In this case, it is necessary for the apparatus 200 to incorporate a stop (not illustrated in FIG. 2) between the lower reaction space 202 and the upper part of the apparatus 200, which provides the electron beam 227, in order to prevent an excessively low vacuum in the upper part of the apparatus 200.

Each of the supply containers 250, 255, 260, 265, 270 and 275 may have its own temperature setting element and control element that enables both cooling and heating of the corresponding supply containers. This makes it possible to store and provide the deposition gases, the additive gases and the etching gases at the respective optimum temperature (not shown in FIG. 2). Further, the vapor pressure of the precursor gas or gases can be regulated by way of the temperature in the supply container or containers in the case of solid or liquid precursors. The gas volumetric flow rate of gaseous precursors can be controlled with the aid of a mass flow controller (MFC).

Furthermore, each feeder system 252, 257, 262, 267, 172 and 277 may comprise its own temperature setting element and temperature control element in order to provide all the process gases at their optimum processing temperature at the point of incidence of the electron beam 227 on the sample 205 (likewise not indicated in FIG. 2). The control device 245 of the computer system 240 can control the temperature setting elements and the temperature control elements both of the supply containers 250, 255, 260, 265, 270, 275 and of the gas feed line systems 252, 257, 262, 267, 272, 277, and can regulate the gas volumetric flow rate through the MFC or MFCs.

The apparatus 200 in FIG. 2 comprises a pump system for producing and maintaining a vacuum required in the reaction chamber 202 (not shown in FIG. 2). With closed control valves 251, 256, 261, 266, 271, 276, a residual gas pressure of ≤10⁻⁶ mbar is achieved in the reaction chamber 202 of the apparatus 200. The pump system may comprise separate pump systems for the upper part of the apparatus 200 for providing the electron beam 227, and the lower part comprising the reaction chamber 202 with the sample stage 210 with the sample 205. Further, the apparatus 200 can comprise a suction extraction apparatus in the vicinity of the processing point 229 of the electron beam 227 in order to define a defined local pressure condition at the surface of the sample 205 (not illustrated in FIG. 2). The use of an additional suction extraction device can largely prevent one or more volatile reaction products of the deposition gases, additive gases and the etching gases which are not needed in the local particle beam-induced processes from depositing on the sample 205 and/or in the reaction chamber 202. The functions of the pump system or systems and of the additional suction extraction apparatus can likewise be controlled and/or monitored by the control device 245 of the computer system 240.

The control device 245, the computer system 240 or a dedicated component of the computer system 240 can determine the size of one or more reference marks 160 for an identified defect 120. The size of a reference mark 160 comprises the determination of both its area and its height. Further, the control device 245, the computer system 240 or a specific component of the computer system 240 can be used to determine a scanning region of the electron beam 227 that is used to scan the position of the reference mark(s) 160. The control device 245 and/or the computer system 240 is able to determine a size of the sacrificial layer(s) 130 on the basis of this knowledge.

The control device 245 typically chooses the area of the sacrificial layer 140 to be twice the size of the area of the scanning region in order to take account of a drift between the sample 205 and the particle beam 227 during an analysis and/or a repair process. Further, with knowledge of the material composition of the sample 205, the control device 245 is able to select a precursor gas for depositing one or more sacrificial layers 140. Moreover, the control device 245 can select one or more precursor gases and optionally an additive gas for depositing one or more reference marks 160 on the sacrificial layers 140. By choosing suitable material compositions of the sacrificial layer(s) 140 and of the reference marks 160, it is possible to optimize the visibility of the reference marks 160 against the background of the sacrificial layer(s) 140.

Like for the reference mark 160, the size of a sacrificial layer 140 also comprises the thickness of the sacrificial layer 140 in addition to its lateral dimensions. This is designed so that it withstands a specified number of scanning procedures of the particle beam 227. Further, the thickness of the sacrificial layer 140 is chosen such that components of a repair process carried out in the direct vicinity are able to be deposited on the sacrificial layer 140 without destroying the latter. Finally, the material composition of the sacrificial layer 140 is chosen such that the latter can be removed from the sample 205 by use of a cleaning process, for example a wet chemical and/or a mechanical cleaning process.

The lower partial image in FIG. 2 shows a cleaning apparatus 290 which has a cleaning liquid 295 used to clean the sample 205 before, during and/or following the termination of a processing procedure within the apparatus 200, during the course of which one or more sacrificial layers 140 and one or more reference marks 160 are deposited. The sacrificial layer(s) 140 and the reference mark(s) 160 are jointly removed from the sample 205 in a conventional cleaning process. The cleaning apparatus 290 may comprise one or more ultrasonic sources and/or a plurality of megasonic sources (not represented in FIG. 2), which are able to generate an ultrasonic and/or megasonic excitation of the cleaning liquid 295. Moreover, the cleaning apparatus 290 may comprise one or more light sources which emit in the ultraviolet (UV) and/or in the infrared (IR) spectral range and which can be used to assist a cleaning process.

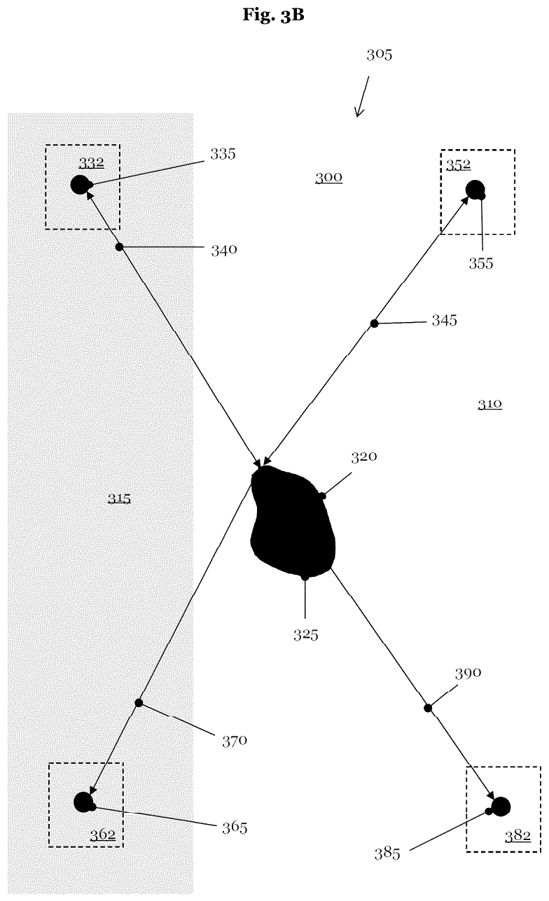

FIG. 3A elucidates a plan view of a section 305 on the substrate 310 of a photomask 300. The section 305 of the mask 300 comprises a pattern element 315 and a defect 320 of the substrate 310. In the example illustrated in FIG. 3A, the substrate 310 has a defect 320 of missing material, which is intended to be repaired using a particle beam-induced processing process. However, the defect 320 could also be a defect of excess material. In order to be able to compensate a drift of the particle beam or electron beam 227 during the processing process, the section 305 comprises four second reference marks 335, 355, 365, 385. Like in the subsequent examples, the reference marks 335, 355, 365 and 385 have a cylindrical shape in the example illustrated in FIG. 3A. The diameter of the reference marks 335, 355, 365 and 385 might be 50 nm and the height thereof might comprise 100 nm.

The second reference marks 335, 355, 365 and 385 are deposited on the second sacrificial layers 330, 350, 360, 380. In this case, the two second sacrificial layers 330 and 360 are deposited on the pattern element 315 of the mask 300 and the two second sacrificial layers 350 and 380 are deposited on the substrate of 310 of the mask 300. The second sacrificial layers 330, 350, 360, 380 may be manufactured from a material or a material composition such that these can easily be removed from the mask 300 following the repair of the defect 320, for example with the aid of a standard mask cleaning process. By way of example, molybdenum hexacarbonyl (Mo(CO)₆) can be used as precursor gas for depositing the second sacrificial layers 330, 350, 360 and 380.

The second reference marks 335, 355, 365, 385 are preferably deposited on the sacrificial layers 330, 350, 360, 380 with the aid of another or a second precursor gas. Examples of a second precursor gas include chromium hexacarbonyl (Cr(CO)₆) and tetraethyl orthosilicate (TEOS, Si(OC₂H₅)₄). Manufacturing the second sacrificial layers 330, 350, 360, 380 and the second reference marks 335, 355, 365, 385 from different materials is advantageous. As a result, there is a material contrast in addition to a topography contrast when scanning the second reference marks 335, 355, 365, 385 using the charged particle beam 227. This makes determining the positions of the second reference marks 335, 355, 365, 385 easier.

In FIG. 3A, the dashed rectangles specify the scanning regions 332, 352, 362 and 382 scanned by the particle beam 227 for the purposes of determining the positions of the second reference marks 335, 355, 365, 385. In FIG. 3A, the four double-headed arrows elucidate the second reference distances 340, 345, 370, 390 between the defect 320 and the reference marks 335, 355, 365, 385. The exemplary illustration of FIG. 3A reproduces four second reference marks 335, 355, 365 and 385 for compensating a drift during a part of the processing process of the defect 320. One second reference mark 335, 355, 365, 385 and one reference distance 340, 345, 370, 390 are sufficient to compensate a drift.

As explained below, the four second reference distances 340, 345, 370 and 390 and the four second reference marks 335, 355, 365, 385 are used to compensate a drift while depositing a first sacrificial layer for the purposes of repairing the defect 320. Further, the second reference marks 335, 355, 365, 385 for compensating a drift can be used during a local etching process for removing a sacrificial layer from the defect 320 by etching. Therefore, the second reference marks 335, 355, 365, 385 only serve to position a first sacrificial layer and to compensate a drift while patterning the sacrificial layer in relation to the defect to be repaired. However, they are not used to compensate the drifts during the actual defect repair.

The demands in relation to the placement of the first sacrificial layer are reduced in comparison with those for the actual defect repair. For reasons of process economy, it may therefore be advantageous to directly deposit the second reference marks 335, 355, 365 and 385 on the photomask 300. This modification is elucidated in FIG. 3B.

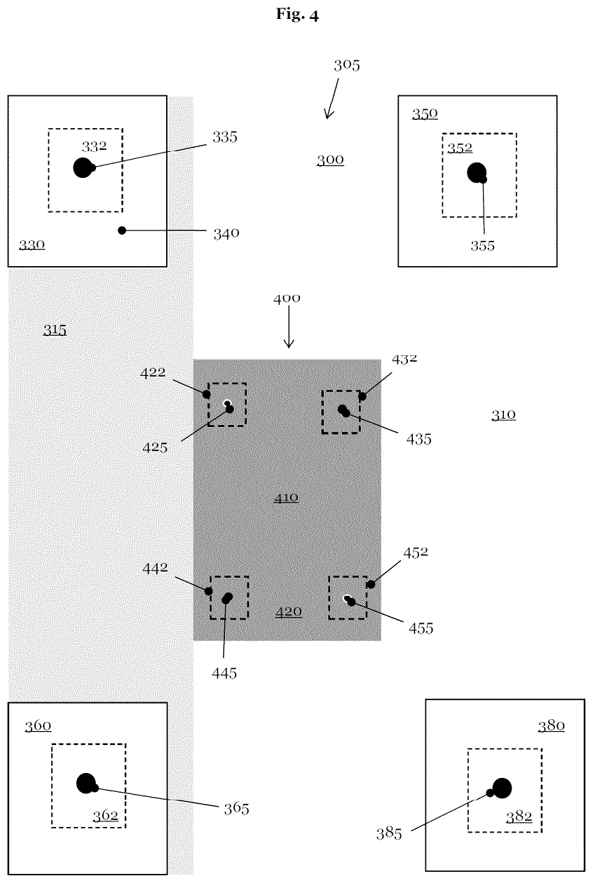

FIG. 4 illustrates a first exemplary embodiment of applying a first sacrificial layer 400 over the defect 320 and around the defect 320 of the mask section 305 in FIG. 3A. The first sacrificial layer 400 is deposited entirely on the substrate 310 of the photomask 310. The first portion 410 of the sacrificial layer 400 covers the defect 320 completely and extends around the defect 320. In a modification, the first portion 410 of the sacrificial layer 400 may only partly cover the defect 320 (not illustrated in FIG. 4). In a further preferred modification, the first sacrificial layer 400 or its first portion 410 is deposited on the substrate 310 of the mask 300 in such a way that the first portion 410 of the first sacrificial layer 400 edges the defect 320 as completely as possible (likewise not shown in FIG. 4). The two last-mentioned modifications may simplify the repair process for the defect 320. As explained above, the second reference marks 335, 355, 365, 385 can be used to compensate a drift and hence to precisely deposit the first sacrificial layer in relation to the defect 320.

In the exemplary embodiment illustrated in FIG. 4, the first portion 410 and the second portion 420 of the first sacrificial layer 400 are interconnected in flush fashion. Four first reference marks 425, 435, 445, 455 have been deposited on the second portion 420 of the first sacrificial layer 400 in the region of the corners of the second portion 420 of the first sacrificial layer 400. The scanning regions 422, 432, 442, 452 scanned by a focused particle beam, for example the electron beam 227, for the purposes of determining the positions of the first reference marks 425, 435, 445, 455 are elucidated in FIG. 4 by the dashed rectangles 422, 432, 442, 452.

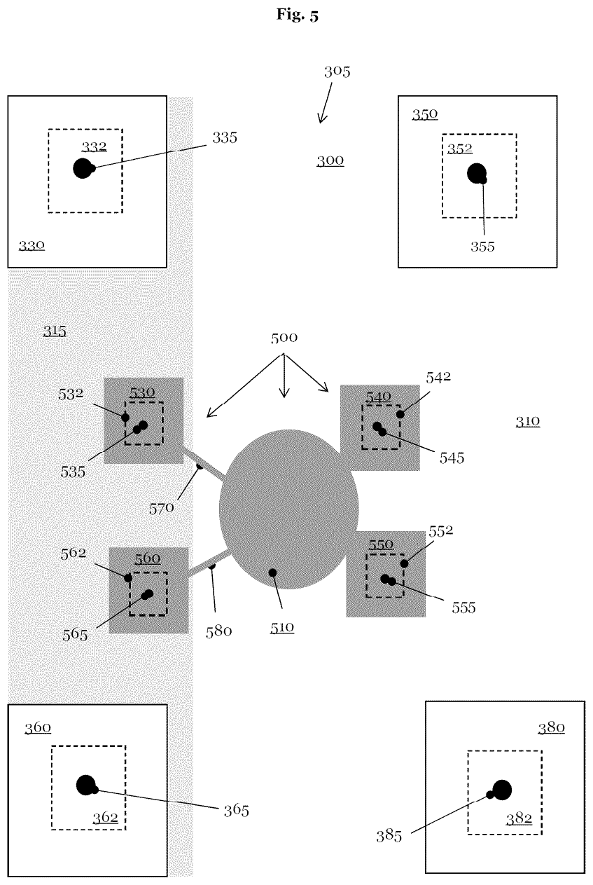

FIG. 5 shows a second exemplary embodiment of a first sacrificial layer 500 which is deposited on and around the defect 320 of the mask 300. In the example of FIG. 5, the first portion 510 of the first sacrificial layer 500 likewise covers the defect 320 in full and additionally extends beyond the edge of the defect 320. Further, the first sacrificial layer 500 comprises a first second portion 530, a second second portion 540, a third second portion 550 and a fourth second portion 560. The second second portion 540 and the third second portion 550 of the sacrificial layer 500 are deposited on the substrate 310 of the mask 300 and have an overlap with the first portion 510. The first second portion 530 and the fourth second portion 560 are deposited on the pattern element 315 of the mask 300 and are connected to the first portion 510 of the first sacrificial layer 500 by way of the electrically conductive webs 570 and 580 or the electrically conductive connections 570 and 580. The size of the first portion 510 of the first sacrificial layer 500 is determined by the size of the defect 320 and the focal diameter of the particle beam 227 used to repair the defect 320.

The second exemplary embodiment of a first sacrificial layer 500 elucidates the flexibility with which a first sacrificial layer can be designed. By virtue of a part of the second portions being arranged on the pattern element 315 it is possible to minimize possible damage to the mask caused by the defect repair. Moreover, it is possible to avoid the focused particle beam 227 having to scan over the edge of the pattern element 315 for the purposes of determining the positions of the reference marks 535, 565. As a result, the precision with which the position of the reference marks 535, 565 is determined can be optimized.

A respective first reference mark 535, 545, 555, 565 is deposited on each of the four second portions 530, 540, 550, 560 of the sacrificial layer 500. Further, the scanning regions 532, 542, 552, 562 of a focused particle beam for detecting the first reference marks 535, 545, 555, 565 are plotted in the second portions 530, 540, 550, 560 of the first sacrificial layer 500. The areas of the four second portions 530, 540, 550, 560 of the first sacrificial layer 500 are dimensioned such that the focused particle beam 227 only scans over the second portions 530, 540, 550, 560 of the first sacrificial layer, even in the case of a relatively large drift of the focused particle beam 227 for repairing the defect 320. Uncontrollable local electrostatic charging of the first sacrificial layer 500 can be reliably avoided as a result. The diameter of the reference marks 425, 435, 445, 455, 535, 545, 555 and 565 might be 50 nm and the height thereof might be 100 nm.

The first sacrificial layer 400, 500 has an electrically conductive material composition. By way of example, the sacrificial layer 400, 500 may be deposited on the substrate 310 of the mask 300 or on the pattern element 315 of the mask 300 by carrying out a local particle beam-induced deposition process with the aid of a precursor gas, for example by use of molybdenum hexacarbonyl (Mo(CO)₆), and optionally with the addition of an additive gas, for example an oxidizing agent. Naturally, another material, for instance chromium hexacarbonyl (Cr(CO)₆), can also be used to deposit the first conductive sacrificial layer 400, 500.

The first portion 410 and the second portion 420 have the same material composition in the case of the first sacrificial layer 400 from FIG. 4. In the case of the first sacrificial layer 500 from FIG. 5, the first portion 510 and the four second portions 530, 540, 550, 560 and the two conductive connections 570, 580 may likewise be deposited from a single precursor gas. However, it is likewise possible to deposit the first portion 510 and the second portions 530, 540, 550, 560 and also the electrically conductive connections on the substrate of 310 or the pattern element 315 of the mask 300 with the aid of different precursor gases.

It is advantageous to dimension the area of the first sacrificial layer 400, 500 to be as large as possible. As a result, electrostatic charging produced when scanning the first reference marks 530, 540, 550, 560 within the scope of etching the defect 320 free and/or repairing the defect can be distributed over a large area. Consequently, the produced electrostatic charges only cause a small change in the electrostatic potential of the first sacrificial layer 400, 500. However, it is particularly important that the electrostatic potential changes uniformly or homogeneously over the entire first sacrificial layer 400, 500. This means that the focused particle beam 227 sees substantially the same electrostatic potential and accordingly experiences the same deflection everywhere when scanning the first reference marks 535, 545, 555, 565, when etching the first portion 410, 510 and when processing the defect 320.

The thickness of the first portion 410, 510 of the sacrificial layer 400, 500 is chosen so that the first portion 410, 510 withstands the processing process of the defect 320 without fundamental damage. The thickness of the second portion 420 or the second portions 420, 530, 540, 550, 560 of the first sacrificial layer 400, 500 is designed so that there is no substantial change of the second portion 420 or the second portions 420, 530, 540, 550, 560 even as a result of scanning the first reference marks 425, 435, 445, 455, 535, 545, 555, 565 a plurality or multiplicity of times. The control device 245 and/or the computer system 240 of the apparatus 200 can determine the thicknesses of the first portion 410, 510 and/or of the second portion 420 or second portions 530, 540, 550, 560 of the sacrificial layer 400, 500 on the basis of knowledge about the defect 320 and the focused particle beam 227.

Just as described above in the context of the second sacrificial layers 330, 350, 360, 380 and the second reference marks 335, 355, 365, 385, it is also advantageous for the second portion 420 or the second portions 530, 540, 550, 560 if the first reference marks 425, 435, 445, 455, 535, 545, 555, 565 have a different material composition to the second portion 420 or the second portions 530, 540, 550, 560 of the sacrificial layer 400, 500. The material contrast occurring in addition to the topography contrast simplifies the detection of the first reference marks 425, 435, 445, 455, 535, 545, 555, 565.

Following the deposition of the first sacrificial layer 400, 500 as explained on the basis of FIGS. 4 and 5, the defect 320 completely covered by the first portion 410, 510 in FIGS. 4 and 5 is exposed. Typically, this is implemented by a local particle beam-induced etching process. The etching gas to be used to this end and an additionally required additive gas are chosen on the basis of the material composition of the first portion 410, 510 of the first sacrificial layer 400, 500. The selection of the precursor gas or gases to be used can be undertaken by the control device 245 and/or the computer system 240. Possible etching gases include xenon difluoride (XeF₂), either on its own or in combination with water (H₂O). If the first portion 410, 510 of the first sacrificial layer 400, 500 comprises chromium as essential constituent, it is possible to use nitrosyl chloride (NOCl) in combination with water (H₂O) as precursor gas in the local particle beam-induced etching process for etching the defect 320 free.

A drift of the focused particle beam 227 relative to the defect is compensated with the aid of the second reference distances 340, 345, 370, 390 and the second reference marks 335, 355, 365, 385. To this end, the local etching process is interrupted at regular or irregular time intervals and the focused particle beam 227 of the apparatus 200 scans over the second sacrificial layers 330, 350, 360, 380 in order to determine the positions of the second reference marks 335, 355, 365, 385. From the measurement data, the control device 245 and/or the computer system 240 determines an arising drift and corrects the latter.

The defect 320 depicted in FIG. 3A is a defect of missing material from the substrate 310 of the photomask 300. Should the defect 320 be a defect of excess material, etching the defect free and etching the defect can be implemented in a single process step. A drift of the first part of the local etching process is corrected with the aid of the second reference marks 335, 355, 365, 385. The drift of the second part of the local etching process, within the scope of which the actual defect is etched, is corrected with the aid of the first reference marks 425, 435, 445, 455, 535, 545, 555, 565. On the basis of the detected back-scattered electron and/or secondary electron spectrum, the device 200 is able to recognize whether it is the first portion 410, 510 of the first sacrificial layer 400, 500 or the defect 320 that is etched. If need be, the etching gas or the combination of etching gas and additive gas can be adjusted to the etching progress.

The sacrificial layer 400, 500 completely covers the defect 320 in the examples of FIGS. 4 and 5. Before processing the defect 320, a defect of missing substrate material, the part of the first portion 410, 510 of the first sacrificial layer 400, 500 which covers the defect 320 must be removed from the defect 320. It is therefore advantageous if the first portion 410, 510 of the first sacrificial layer 400, 500 does not fully cover the defect (not illustrated in FIGS. 4 and 5). If the first portion 410, 510 extends over only parts of the defect 320, less material has to be removed from the defect 320 before the actual defect repair. In the best possible case, the first portion 410, 510 of the first sacrificial layer 400, 500 extends over the entire edge 325 of the defect 320. The etching step of the first portion 410, 510 of the sacrificial layer 400, 500 can be economized as a result. As already explained above, the second reference marks 335, 355, 365 and 385 can be used for precisely depositing the first portion 410, 510 of the sacrificial layer 400, 500 by correcting a drift during the deposition procedure.

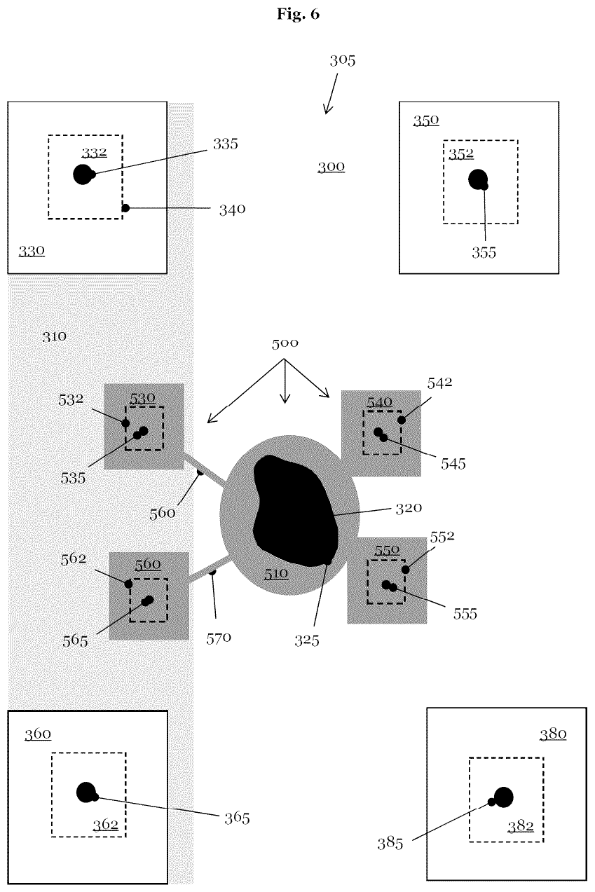

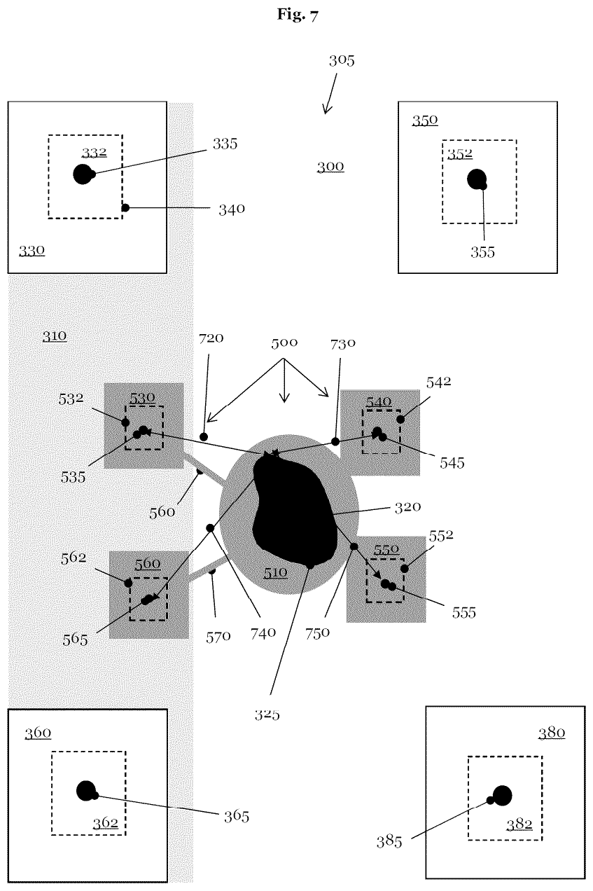

The reference distances 720, 730, 740, 750 between the first reference marks 535, 545, 565, 555 and the defect 320 etched free are still determined before the start of the actual defect processing process. The reference distances 720, 730, 740, 750 are reproduced in FIG. 7. Otherwise FIG. 7 corresponds to FIG. 6. Determining the reference distances 720, 730, 740, 750 can be implemented by scanning the defect 320 and the first reference marks 535, 545, 565, 555 using the focused particle beam 227. The control device 245 and/or the computer system 240 of the apparatus 200 can determine the reference distances 720, 730, 740, 750 from the measurement data.

The first reference marks 425, 435, 445, 455, 535, 545, 555, 565 and the first reference distances 720, 730, 740, 750 can now be used during the processing of the defect 320 with the aid of a particle beam-induced deposition process for the purposes of correcting a drift of the focused particle beam 227 relative to the defect 320 to be repaired. To this end, the local deposition process is interrupted at regular or irregular time intervals and the first reference marks 535, 545, 555, 565 are scanned using the focused particle beam 227. From the measurement data obtained thus, the control device 245 and/or the computer system 240 is able to determine and correct an occurred drift. A silicon-containing precursor gas, for instance tetraethyl orthosilicate (TEOS, Si(OC₂H₅)₄), can be used to fill the defect 320 with material of the substrate 310 of the mask 300.

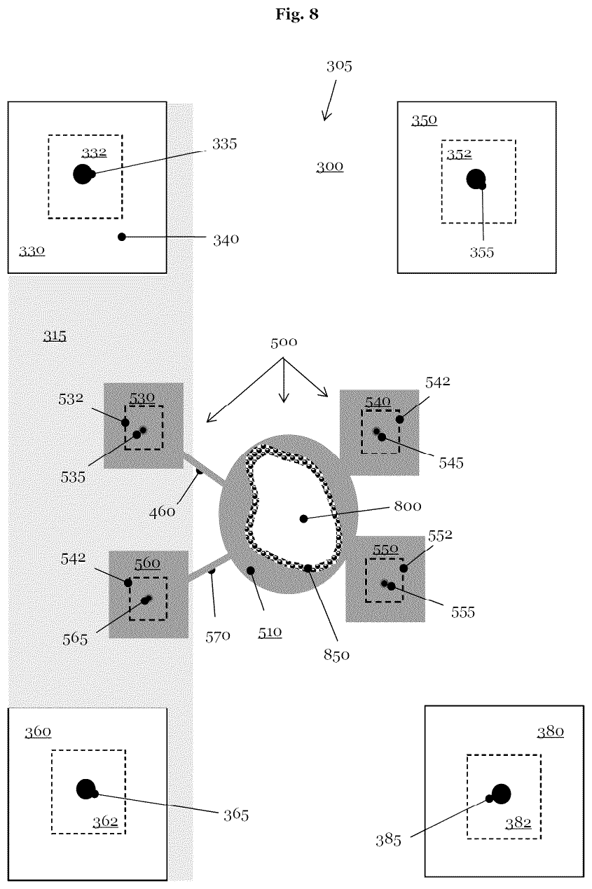

As elucidated in FIGS. 6 and 7, the first portion 410, 510 of the sacrificial layer 400, 500 extends around the entire defect 320. As a result, the first portion 410, 510 of the sacrificial layer 400, 500 is able to effectively protect the substrate 310 of the photomask 300 surrounding the defect 320 from the effects of the local deposition processes occurring in the direct vicinity thereof. FIG. 8 illustrates the mask section 305 after termination of the repair process for the defect 320. The defect 320 has been fully removed by depositing substrate material 800. However, the local deposition process has undesirably also deposited substrate material 800 on the first portion 410, 510 of the first sacrificial layer 400, 500 around the defect 320. This is elucidated by the reference sign 850 in FIG. 8.

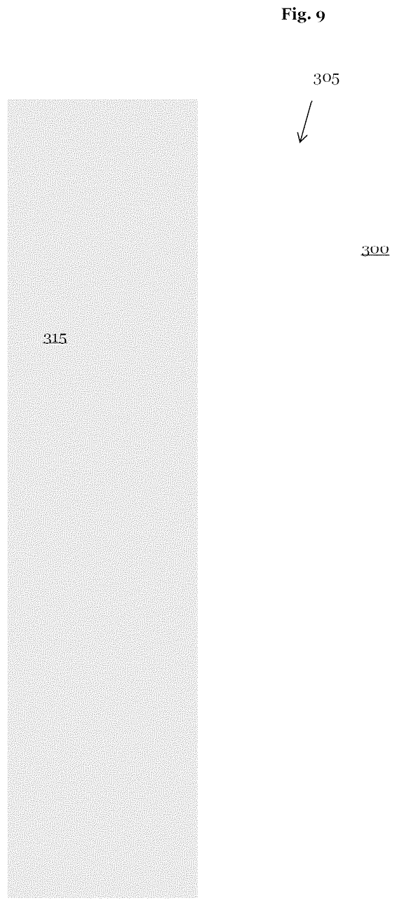

FIG. 9 reproduces an SEM image of a section 305 of the photolithographic mask 300 from FIG. 3A following the removal of the second sacrificial layers 330, 350, 360, 380 with associated second reference marks 335, 355, 365, 385 and the first sacrificial layer 400, 500 with the corresponding first reference marks 425, 435, 445, 455, 535, 545, 555, 565. The sacrificial layers 330, 350, 360, 380, 400, 500 with the reference marks 335, 355, 365, 385, 425, 435, 445, 455, 535, 545, 555, 565 situated thereon and the substrate material 800 in the edge region 850 of the first portion 510 of the sacrificial layer 500 have been removed from the photomask 300 substantially without residue by the cleaning liquid 295 of the cleaning apparatus 290. It is a significant advantage of the described method that the assistance structures deposited on a sample 205 can be removed from the sample 205 after termination of a defect correction process with the aid of a standard cleaning process (for example, conventional mask cleaning).

However, it is also possible to remove a part or the entirety of the sacrificial layers 330, 350, 360, 380, 400, 500 with the reference marks 335, 355, 365, 385, 425, 435, 445, 455, 535, 545, 555, 565 situated thereon from the mask 300 with the aid of a local particle beam-induced etching process. This procedure may be advantageous in the case where the intention is to remove one or more further defects from a sample 205, with the deposited assistance structures possibly interfering. The alternative removal can be carried out in the apparatus 200 without the sample 205 having to be removed from the apparatus 200 with associated breaking of the vacuum.

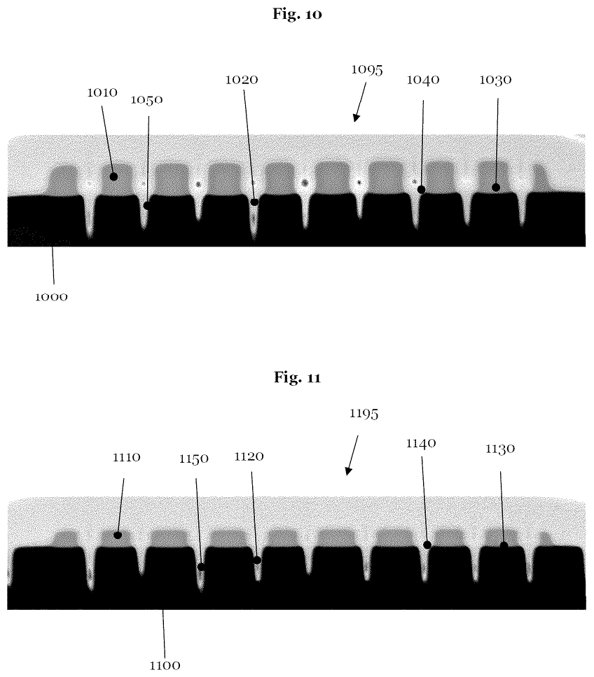

The diagram 1095 from FIG. 10 shows a recording of a section of a stamp 1000 for nanoimprint lithography (NIL). Just like the subsequent diagram 1195 from FIG. 11, the recording in the diagram 1095 of FIG. 10 reproduces a scanning transmission electron microscope (STEM) recording which was recorded with the aid of a high-angle annular dark field (HAADF).

The intention is to etch depressions 1020 with periodic spacings or irregular spacings into the NIL stamp 1000. The etching process is carried out using the apparatus 200 described on the basis of FIG. 2. This means that an EBIE process is carried out. In order to protect the stamp 1000 during the local etching process, a sacrificial layer 1010 in the form of a “hard mask” has been deposited, over the full area, onto the region of the stamp 1000 to be processed, that is to say the region in which the depressions 1020 are intended to be produced. The sacrificial layer 1010 is deposited on the stamp 1000 with the aid of an EBID process using a precursor gas. The molybdenum hexacarbonyl (Mo(CO)₆) precursor gas is used in the examples of FIGS. 10 and 11. The diagram 1095 has a thick sacrificial layer 1010. A thick sacrificial layer 1010 may have a thickness of the order of 100 nm.

In the examples that are produced in FIGS. 10 and 11, the depressions 1020 are etched through the sacrificial layer 1010. The sacrificial layer 1010 has the function of, during the etching process, effectively protecting the surface 1030 of the stamp 1000 around the depressions 1020 to be produced. Further, the sacrificial layer 1010 is intended to minimize the edge rounding 1040 that occurs when etching on the surface 1030 of the NIL stamp 1000. Moreover, an object of the sacrificial layer 1010 is that of maximizing the side wall angle 1050 of the produced depression 1020 such that the etched depressions 1020 have a side wall angle 1050 which comes as close as possible to a right angle in relation to the surface 1030 of the stamp 1000.

The diagram 1195 of FIG. 11 reproduces the diagram 1095 of FIG. 10, with the difference that the sacrificial layer 1110 deposited on the basis of the molybdenum hexacarbonyl (Mo(CO)₆) precursor gas only has a smaller thickness. By way of example, the thickness of the sacrificial layer 1110 in FIG. 11 may be approximately half that of the sacrificial layer 1010 in FIG. 10.

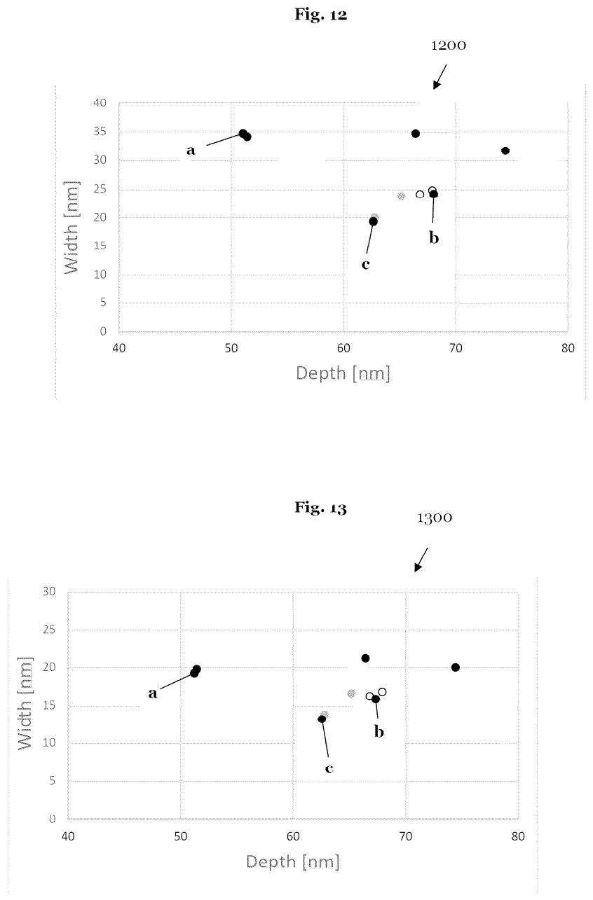

The diagrams 1200, 1300 and 1400 in FIGS. 12 to 14 present measurement data of the depressions 1020, 1120 of the NIL stamps 1000 and 1100 depicted in FIGS. 10 and 11. The measurement data of the depressions 1120 that were etched through a thin sacrificial layer 1110 are denoted by the letter (b) in the diagrams 1200 to 1400. The measurement data of the lamellas 1020 that were etched through a thick sacrificial layer 1010 are represented by the letter (c) in the diagrams 1200 to 1400. For comparison purposes, an etching process for producing the depressions 1020, 1120 was carried out on an NIL stamp without a preceding application of a protective sacrificial layer 1010, 1110. In the following diagrams 1200 to 1400, the measurement data of this etching process are labelled by the letter (a).

The diagram 1200 in FIG. 12 shows the width of the produced depressions 1020, 1120 as a function of the etching depths. In the measurement data presented in FIG. 12, the width or the diameter of the etched depressions 1020, 1120 is measured at a depth corresponding to 10% of the specified etching depth. In comparison with etching within the scope of which the NIL stamp 1000, 1100 is covered by no sacrificial layer 1010, 1110, the etched depressions without a protective sacrificial layer 1010, 1110 (a) have a significantly larger diameter.

The diagram 1300 of FIG. 13 reproduces the measurement data of the etched depressions 1020, 1120, wherein the width of the depressions 1020, 1120 or the diameter thereof was measured at a depth corresponding to 50% of the nominal etching depth. Even at a depth of 50%, depressions 1020, 1120 produced without a sacrificial layer 1010, 1110 still have a greater diameter than depressions 1020, 1120 that were etched through a sacrificial layer 1010, 1110. However, from a comparison of the diagrams 1200 and 1300, it is evident that the differences reduce with increasing distance from the surface 1030, 1130.

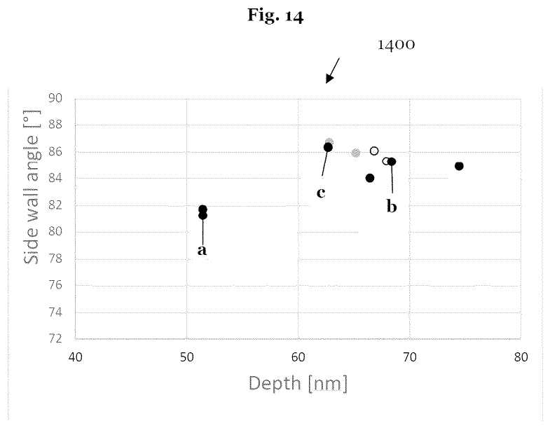

The diagram 1400 in FIG. 14 represents the measured side wall angle of the three described measurement data sets as a function of the generated depression 1020, 1120. With an applied sacrificial layer 1010, 1110, the side wall angle of an etched depression 1020, 1120 is increased in comparison with an EBIE process carried out without the protection of a sacrificial layer 1010, 1110.

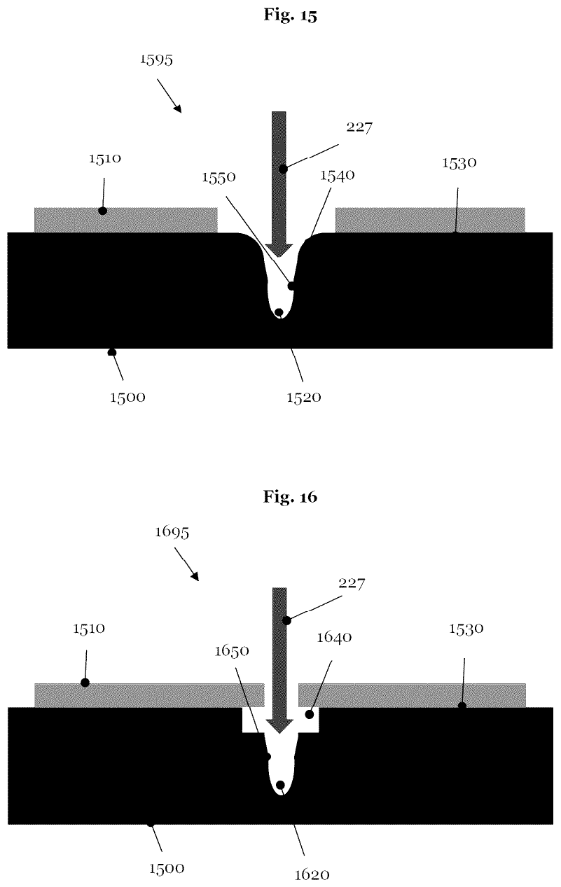

The diagrams 1595, 1695 and 1795 in FIGS. 15 to 17 show a magnified section of the etching processes elucidated in FIGS. 10 and 11 for producing a depression in an NIL stamp with the aid of an EBIE process. The EBIE process is carried out by the focused particle beam 227 of the apparatus 200 in combination with an etching gas and optionally an additive gas. As already explained above, the preferred particles of the focused particle beam 227 are electrons.

Before the depression 1520, 1620, 1720 is etched, a sacrificial layer 1510 is deposited on the surface 1530 of the part in which the depression 1520, 1620, 1720 is intended to be manufactured. This means that the etching process—as explained in the examples of FIGS. 10 and 11—is implemented through the sacrificial layer 1510. The sacrificial layer 1510 can be one of the sacrificial layers 1010, 1110 of FIGS. 10 and 11. Naturally, a different precursor gas, for instance a different metal carbonyl, for example chromium hexacarbonyl (Cr(CO)₆), can be used for the purposes of depositing the sacrificial layer 1510.

The diagram 1595 in FIG. 15 elucidates the result of an etching process, in which use is made of an etching gas, a combination of two or more etching gases or an etching gas and an additive gas, which etches the sacrificial layer 1510 at a greater rate than the material of the NIL stamp 1500. As a result of the greater etching rate of the sacrificial layer 1510, the latter withdraws ever further from the edge of the planned depression 1520 with increasing etching duration. The surface 1530 of the stamp 1500 freed in the process is exposed to the further effect of the EBIE process without protection. The edge of the surface 1530 along the depression 1520 experiences significant rounding 1540 as a result of the particle beam-induced etching process. Moreover, the EBIE process tends to generate a depression 1520 with a funnel-shaped structure with a side wall angle 1550 significantly less than 90°.

The diagram 1695 in FIG. 16 illustrates the result of an EBIE process in which the material of the stamp 1500 is etched at a greater rate than the material of the sacrificial layer 1010. Once the particle beam-induced etching process has produced an opening in the sacrificial layer 1510, said process progresses at a greater rate within the stamp 1500 than within the sacrificial layer 1510. This generates undesirable under-etching 1640 of the sacrificial layer 1510. Moreover, the side wall angle 1650 of the depression 1620 deviates significantly from the specified right angle in relation to the surface 1530 of the stamp 1500. Overall, the generated depression 1620 deviates drastically from the specified cylindrical shape.

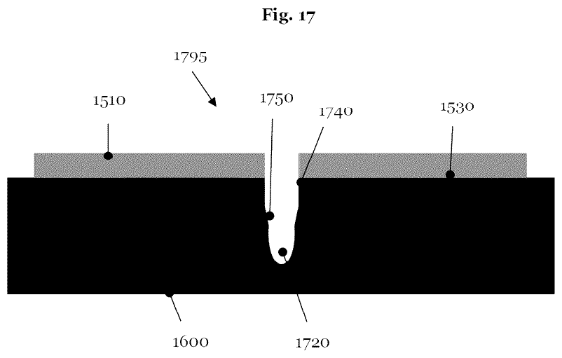

The diagram 1795 in FIG. 17 presents a depression 1720 after completion of an EBIE process, the etching gas of which etches the material of the sacrificial layer 1510 and the material of the NIL stamp 1500 at the same rate. The edge rounding 1740 at the transition from the surface 1530 to the depression 1720 is minimized by uniform etching of the sacrificial layer 1510 and of the stamp 1500. Moreover, an EBIE process which etches the sacrificial layer 1510 and the stamp 1500 at the same rate produces a maximally large side wall angle 1750.

Therefore, when implementing a particle beam-induced etching process through a sacrificial layer 1510, it is particularly advantageous to design the EBIE process in such a way that the condition of the same etching rate for a sacrificial layer 1510 and a sample 205, 300, 1500 is satisfied. Given an etching gas, this can be implemented by the choice of a suitable material for the sacrificial layer 1510. Given the material of the sacrificial layer 1510, it is possible to choose an etching gas, a combination of various etching gases and/or an etching gas and at least one additive gas, which etches the sacrificial layer 1510 and the sample 205, 300, 1500 at substantially the same rate. It is particularly advantageous if it is possible to choose both the material of the sacrificial layer 1510 and the etching gas.

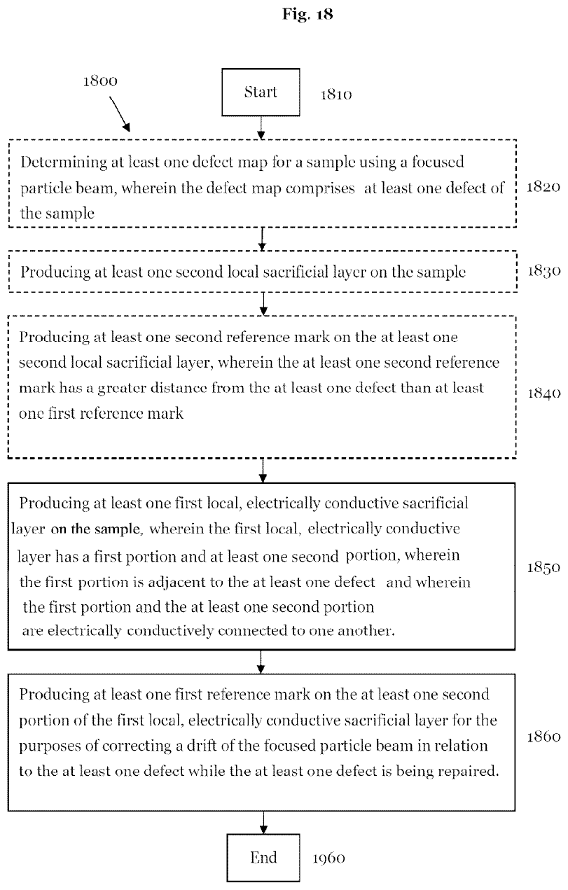

Finally, FIG. 18 shows a flowchart 1800 of a method for repairing a defect 320 of a sample 205, 300, 1500, as described in this application. The method begins in step 1810. A defect map for a sample 205, 300, 1500 is determined in a first step 1820 using a focused particle beam 227. The defect map includes at least one defect 320. The at least one defect 320 of a sample 205, 300, 1500 can be scanned using the focused particle beam 227 of the apparatus 200. The control apparatus 245 and/or the computer system 240 of the apparatus 200 can determine a defect map for the sample 205, 300, 1500 from the measurement data generated by the focused particle beam 227.

At least one second local sacrificial layer 330, 350, 360, 380 is produced on the sample 205, 300, 1500 in the next step 1830. The at least one second local sacrificial layer 330, 350, 360, 380 can be deposited on the sample 205, 300, 1500 by the apparatus 200 by way of carrying out an EBID process.

Thereupon, at least one second reference mark 335, 355, 365, 385 is produced on the at least one second local sacrificial layer 330, 350, 360, 380 in step 1840. The at least one second reference mark 335, 355, 365, 385 has a greater distance from the at least one defect 320 than the at least one first reference mark 425, 435, 445, 455, 535, 545, 555, 565. The at least one second reference mark 335, 355, 365, 385 can be produced by the apparatus 200 by way of carrying out a particle beam-induced deposition process.

The steps 1820, 1830 and 1840 are optional steps of a method for repairing at least one defect 320 of a sample 205, 300, 1500. Therefore, these steps are symbolized by dashed edges in FIG. 18.

In step 1850, at least one first local, electrically conductive sacrificial layer 400, 500 is produced, wherein the first local, electrically conductive sacrificial layer 400, 500 has a first portion 410, 510 and at least one second portion 420, 530, 540, 550, 560, wherein the first portion 410, 510 is adjacent to the at least one defect 320 and wherein the first portion 410, 510 and the at least one second portion 420, 530, 540, 550, 560 are electrically conductively connected to one another. The apparatus 200 can produce the first local, electrically conductive sacrificial layer 400, 500 on the sample 205, 300, 1500 by carrying out an EBID process.

In the next step 1860, at least one first reference mark 425, 435, 445, 455, 535, 545, 555, 565 is produced on the at least one second part 420, 530, 540, 550, 560 of the first local, electrically conductive sacrificial layer 400, 500 for the purposes of correcting a drift of the focused particle beam 227 in relation to the at least one defect 320 while the at least one defect 320 is being repaired. This process step can be carried out with the aid of the focused particle beam 227 of the apparatus 200 in combination with at least one precursor gas. Finally, the method ends in step 1870.

In the following, further embodiments are described to facilitate the understanding of the invention:
1. A method (1800) for repairing at least one defect (320) of a sample (205, 300, 1500) using a focused particle beam (227), the method (1800) comprising the steps of:
   a. producing (1850) at least one first local, electrically conductive sacrificial layer (400, 500) on the sample (205, 300, 1500), wherein the first local, electrically conductive sacrificial layer (400, 500) has a first portion (410, 510) and at least one second portion (420, 530, 540, 550, 560), wherein the first portion (410, 510) is adjacent to the at least one defect (320) and wherein the first portion (410, 510) and the at least one second portion (420, 530, 540, 550, 560) are electrically conductively connected to one another (570, 580); and
   b. producing (1860) at least one first reference mark (425, 435, 445, 455, 535, 545, 555, 565) on the at least one second portion (420, 530, 540, 550, 560) of the first local, electrically conductive sacrificial layer (400, 500) for the purposes of correcting a drift of the focused particle beam (227) in relation to the at least one defect (320) while the at least one defect (320) is being repaired.
2. The method (1800) of embodiment 1, wherein the adjacency of the first portion (410, 510) to the at least one defect (320) comprises at least one element from the following group: adjacency of the first portion (410, 510) to an edge (325) of the at least one defect (320), partial coverage of the at least one defect (320) by the first portion (410, 510) and complete coverage of the at least one defect (320) by the first portion (410, 510).
3. The method (1800) of embodiment 1, further comprising: determining at least one first reference distance (720, 730, 740, 750) between the at least one first reference mark (425, 435, 445, 455, 535, 545, 555, 565) and the at least one defect (320) before the repair of the at least one defect (320) has started.
4. The method (1800) of embodiment 1, wherein the at least one second portion (430, 530, 540, 550, 560) extends over at least one scanning region (422, 432, 442, 452, 532, 542, 552, 562) of the focused particle beam (227) for the purposes of detecting the at least one first reference mark (425, 435, 445, 455, 535, 545, 555, 565).
5. The method (1800) of embodiment 1, wherein the production of the first local, electrically conductive sacrificial layer (400, 500) comprises: depositing the first local, electrically conductive sacrificial layer (400, 500) by the focused particle beam (227) in combination with at least one first precursor gas.
6. The method (1800) of embodiment 1, wherein the production of the at least one first reference mark (425, 435, 445, 455, 535, 545, 555, 565) comprises: depositing the at least one first reference mark (425, 435, 445, 455, 535, 545, 555, 565) using the focused particle beam (227) in combination with at least one second precursor gas.
7. The method (1800) of embodiment 1, further comprising: removing the part of the first portion (410, 510) of the first sacrificial layer (400, 500) which covers the at least one defect (320), before the at least one defect (320) is repaired.
8. The method (1800) of embodiment 1, wherein the at least one defect (320) comprises a defect of excess material and wherein the method (1800) further comprises: repairing the at least one defect (320) at least partly through the first sacrificial layer (400, 500, 1510).
9. The method (1800) of embodiment 1, wherein the first portion (410, 510) and the at least one second portion (420, 530, 540, 550, 560) of the first sacrificial layer (400, 500) have lateral extents such that the action of repairing the at least one defect (320) distorts an image section comprising the at least one defect (320) by no more than 10%, preferably by no more than 5%, more preferably by no more than 2% and most preferably by no more than 1%.
10. The method (1800) of embodiment 1, wherein the at least one defect (320) comprises a defect of excess material and wherein the action of repairing the at least one defect comprises: choosing a material composition of the first portion (410, 510) of the first sacrificial layer (400, 500, 1510), of a second etching gas, and/or of at least one additive gas such that an etching rate of an etching process induced by a focused particle beam is substantially the same for the at least one defect (320) and the first portion (410, 510).
11. The method (1800) of embodiment 1, further comprising: scanning the sample (205, 300, 1500) with the focused particle beam (227) for the purposes of producing a defect map of the sample (205, 300, 1500).
12. The method (1800) of embodiment 1, further comprising: producing at least one second reference mark (335, 355, 365, 385) on the sample (205, 300, 1500) and determining at least one second reference distance (340, 345, 370, 390) between the at least one second reference mark (335, 355, 365, 385) and the at least one defect (320) before the production of the first sacrificial layer (400, 500) has started.
13. The method (1800) of embodiment 1, further comprising: producing at least one second sacrificial layer (330, 350, 360, 380) on the sample (205, 300, 1500), depositing at least one second reference mark (335, 355, 365, 385) on the at least one second sacrificial layer (330, 350, 360, 380) and determining at least one second reference distance (340, 345, 370, 390) between the at least one second reference mark (335, 345, 365, 385) and the at least one defect (320) before the production of the first sacrificial layer (400, 500) has started.
14. The method (1800) of embodiment 1, wherein the at least one second reference distance (340, 345, 370, 390) is greater than the at least one first reference distance (720, 730, 740, 750).
15. The method (1800) of embodiment 1, further comprising: correcting a drift while implementing at least one element from the following group: producing the first sacrificial layer (400, 500) and removing a part of the first portion (410, 510) of the first sacrificial layer (400, 500) which covers the at least one defect (320) from the at least one defect (320) by using the at least one second reference mark (335, 355, 365, 385) and the at least one second reference distance (340, 345, 370, 390).
16. The method (1800) of embodiment 1, further comprising: jointly removing the first sacrificial layer (400, 500) and the at least one first reference mark (425, 435, 445, 455, 535, 545, 555, 565) from the sample (205, 300, 1500) within the scope of a wet chemical and/or mechanical cleaning process.
17. The method (1800) of embodiment 1, further comprising: jointly removing the first sacrificial layer (400, 500), the at least one first reference mark (425, 435, 445, 455, 535, 545, 555, 565) and the at least one second reference mark (335, 355, 365, 385) from the sample (205, 300, 1500) within the scope of a wet chemical and/or mechanical cleaning process.
18. A computer program comprising instructions which prompt a computer system (240) to execute the method steps according to any one of embodiments 1 to 17.
19. An apparatus (200) for repairing at least one defect (320) of a sample (205, 300, 1500) using a focused particle beam (227), comprising:
   a. means for producing at least one first local, electrically conductive sacrificial layer (400, 500) on the sample (205, 300, 1500), wherein the first local, electrically conductive sacrificial layer (400, 500) has a first portion (410, 510) and at least one second portion (420, 530, 540, 550, 560), wherein the first portion (410, 510) is adjacent to the at least one defect (320) and wherein the first portion (410, 510) and the at least one second portion (420, 530, 540, 550, 560) are electrically conductively connected to one another; and
   b. means for producing at least one first reference mark (425, 435, 445, 455, 535, 545, 555, 565) on the at least one second portion (420, 530, 540, 550, 560) of the first local, electrically conductive sacrificial layer (400, 500) for the purposes of correcting a drift of the focused particle beam (227) in relation to the at least one defect (320) while the at least one defect (320) is being repaired.
20. The apparatus (200) of embodiment 19, wherein the means for producing the first sacrificial layer (400, 500) comprises at least one electron beam (227) and wherein the apparatus (200) is configured to focus the electron beam (227) on a diameter <2 nm in the case of a kinetic energy of the electrons striking the sample (205, 300, 1500) of <3000 eV, preferably <1500 eV, more preferably <1000 eV, even more preferably <800 eV, and most preferably <600 eV.
21. The apparatus (200) of embodiment 19, configured to carry out a method according to any one of embodiments 1-17.

What is claimed is:

1. A method for repairing at least one defect of a sample using a focused particle beam, the method comprising:
producing at least one first sacrificial layer on the sample adjacent to the at least one defect for correcting a drift of the focused particle beam in relation to the at least one defect during the repairing of the at least one defect.

2. A method for repairing at least one defect of a sample using a focused particle beam, the method comprising:
producing at least one first electrically conductive sacrificial layer on the sample for correcting a drift of the focused particle beam in relation to the at least one defect during the repairing of the at least one defect.

3. The method of claim 1, wherein the first sacrificial layer comprises a first local, electrically conductive sacrificial layer.

4. The method of claim 2, wherein the first electrically conductive sacrificial layer comprises a first local, electrically conductive sacrificial layer.

5. The method of claim 1, wherein the focused particle beam comprises a focused electron beam.

6. The method of claim 1, further comprising the step of producing at least one first reference mark on the first sacrificial layer.

7. The method of claim 1, wherein the first sacrificial layer has a first portion and at least one second portion, wherein the first portion is adjacent to the at least one defect and wherein the first portion and the at least one second portion are electrically conductively connected to one another.

8. The method of claim 1, further comprising the step of producing at least one first reference mark on the at least one second portion of the first sacrificial layer for correcting a drift of the at least one defect during repairing of the at least one defect.

9. The method of claim 6, further comprising: determining at least one first reference distance between the at least one first reference mark and the at least one defect before repairing the at least one defect.

10. The method of claim 1, wherein the adjacency of the first portion to the at least one defect comprises at least one element from the following group: adjacency of the first portion to an edge of the at least one defect, partial coverage of the at least one defect by the first portion and complete coverage of the at least one defect by the first portion.

11. The method of claim 8, wherein the at least one second portion extends over at least one scanning region of the focused particle beam for detecting the at least one first reference mark.

12. The method of claim 1, wherein producing the first sacrificial layer comprises: depositing the first sacrificial layer by the focused particle beam in combination with at least one first precursor gas.

13. The method of claim 6, wherein producing the at least one first reference mark comprises: depositing the at least one first reference mark using the focused particle beam in combination with at least one second precursor gas.

14. The method of claim 10, further comprising: removing the part of the first portion of the first sacrificial layer which covers the at least one defect, before repairing the at least one defect.

15. The method of claim 1, wherein the at least one defect comprises a defect of excess material and wherein the method further comprises: repairing the at least one defect at least partly through the first sacrificial layer.

16. The method of claim 7, wherein the first and the at least one second portion of the first sacrificial layer have lateral extents such that the action of repairing the at least one defect distorts an image section comprising the at least one defect by no more than 10%, preferably by no more than 5%, more preferably by no more than 2%, and most preferably by no more than 1%.

17. The method of claim 7, wherein the at least one defect comprises a defect of excess material and wherein the action of repairing the at least one defect comprises: choosing a material composition of the first portion of the first sacrificial layer, of a second etching gas, and/or of at least one additive gas such that an etching rate of an etching process induced by a focused particle beam is substantially the same for the at least one defect and the first portion.

18. The method of claim 1, further comprising: scanning the sample with the focused particle beam for producing a defect map of the sample.

19. The method of claim 1, further comprising: producing at least one second reference mark on the sample and determining at least one second reference distance between the at least one second reference mark and the at least one defect before producing the first sacrificial layer.

20. The method of claim 1, further comprising: producing at least one second sacrificial layer on the sample, depositing at least one second reference mark on the at least one second sacrificial layer and determining at least one second reference distance between the at least one second reference mark and the at least one defect before producing the first sacrificial layer.

21. The method of claim 19, further comprising:
producing at least one first reference mark on the first sacrificial layer; and
determining at least one first reference distance between the at least one first reference mark and the at least one defect before repairing the at least one defect;
wherein the at least one second reference distance is greater than the at least one first reference distance.

22. The method of claim 19, further comprising: correcting a drift while performing at least one element from the group of: producing the first sacrificial layer and removing a part of the first portion of the first sacrificial layer which covers the at least one defect from the at least one defect by using the at least one second reference mark and the at least one second reference distance.

23. The method of claim 6, further comprising: jointly removing the first sacrificial layer and the at least one first reference mark from the sample using a wet chemical and/or mechanical cleaning process.

24. The method of claim 19, further comprising:
producing at least one first reference mark on the first sacrificial layer; and
jointly removing the first sacrificial layer, the at least one first reference mark and the at least one second reference mark from the sample using a wet chemical and/or mechanical cleaning process.

25. A computer program comprising instructions which prompt a computer system to execute the method steps of claim 1.

26. An apparatus for repairing at least one defect of a sample using a focused particle beam, comprising:
means for producing at least one first sacrificial layer on the sample (adjacent to the at least one defect for correcting a drift of the focused particle beam in relation to the at least one defect during the repairing of the at least one defect.

27. An apparatus for repairing at least one defect of a sample using a focused particle beam, comprising:
means for producing at least one first electrically conductive sacrificial layer on the sample for correcting a drift of the focused particle beam in relation to the at least one defect during the repairing of the at least one defect.

28. The apparatus of claim 26, wherein the means for producing the first sacrificial layer comprises means for producing a first local electrically conductive sacrificial layer.

29. The apparatus of claim 26, further comprising an electron column having a single-stage condenser system.

30. The apparatus of claim 26, wherein the means for producing the first sacrificial layer comprises at least one electron beam, and wherein the apparatus is configured to focus the electron beam on a diameter <2 nm at a kinetic energy of the electrons striking the sample of <3000 eV.

31. The apparatus of claim 26, wherein the means for producing the first sacrificial layer comprises at least one electron beam, and wherein the apparatus is configured to focus the electron beam on a diameter <2 nm at a kinetic energy of the electrons striking the sample of <1500 eV.

32. The apparatus of claim 26, wherein the means for producing the first sacrificial layer comprises at least one electron beam, and wherein the apparatus is configured to focus the electron beam on a diameter <2 nm at a kinetic energy of the electrons striking the sample of <1000 eV.

33. The apparatus of claim 26, wherein the means for producing the first sacrificial layer comprises at least one electron beam, and wherein the apparatus is configured to focus the electron beam on a diameter <2 nm at a kinetic energy of the electrons striking the sample of <800 eV.

34. The apparatus of claim 26, wherein the means for producing the first sacrificial layer comprises at least one electron beam, and wherein the apparatus is configured to focus the electron beam on a diameter <2 nm at a kinetic energy of the electrons striking the sample of <600 eV.

35. The apparatus of claim 26, wherein a local processing area of the focused particle beam of the apparatus has a minimum diameter <10 nm.

36. The apparatus of claim 26, wherein a working distance between an exit of the electron column and the sample is <5 mm.

37. The apparatus of claim 26, wherein a working distance between an exit of the electron column and the sample is <4 mm.

38. The apparatus of claim 26, wherein a working distance between an exit of the electron column and the sample is <3 mm.

39. The apparatus of claim 26, wherein a working distance between an exit of the electron column and the sample is <2.5 mm.

40. The apparatus of claim 26, wherein the electron column is configured to use a set of different apertures.

41. The apparatus of claim 40, further comprising a control unit configured to control a beam current of the electron beam by selecting an aperture of the set of apertures.

42. The apparatus of claim 26, configured to carry out a method for repairing at least one defect of a sample using a focused particle beam, the method comprising producing at least one first sacrificial layer on the sample adjacent to the at least one defect for correcting a drift of the focused particle beam in relation to the at least one defect during the repairing of the at least one defect.
